(19) United States
(12) Patent Application Publication
(10) Pub. No.: US 2023/0402507 A1
(43) Pub. Date: Dec. 14, 2023

(54) DUAL METAL SILICIDE FOR STACKED TRANSISTOR DEVICES

(71) Applicant: Intel Corporation, Santa Clara, CA (US)

(72) Inventors: Rohit Galatage, Hillsoboro, OR (US); Willy Rachmady, Beaverton, OR (US); Cheng-Ying Huang, Hillsboro, OR (US); Jami A. Wiedemer, Scappoose, OR (US); Munzarin F. Qayyum, Hillsboro, OR (US); Nicole K. Thomas, Portland, OR (US); Patrick Morrow, Portland, OR (US); Marko Radosavljevic, Portland, OR (US); Mauro J. Kobrinsky, Portland, OR (US)

(73) Assignee: Intel Corporation, Santa Clara, CA (US)

(21) Appl. No.: 17/838,637

(22) Filed: Jun. 13, 2022

(51) Int. Cl. H01L 29/06; H01L 27/092; H01L 29/423; H01L 29/417; H01L 29/786

(52) U.S. Cl. CPC H01L 29/0673; H01L 27/0924; H01L 29/42392; H01L 29/41733; H01L 29/78618; H01L 29/78696

(57) ABSTRACT

An integrated circuit structure includes a second device stacked vertically above a first device. The first device includes (i) a first source or drain region, (ii) a first source or drain contact coupled to the first source or drain region, and (iii) a first layer comprising a first metal and first one or more semiconductor materials between at least a section of the first source or drain region and the first source or drain contact. The second device includes (i) a second source or drain region, (ii) a second source or drain contact coupled to the second source or drain region, and (iii) a second layer comprising a second metal and second one or more semiconductor materials between at least a section of the second source or drain region and the second source or drain contact. In an example, the first metal and the second metal are different.

### FIELD OF THE DISCLOSURE

The present disclosure relates to integrated circuits, and more particularly, to stacked transistor devices.

### BACKGROUND

Semiconductor devices are electronic components that exploit the electronic properties of semiconductor materials, such as silicon (Si), germanium (Ge), gallium arsenide (GaAs), and indium phosphide (InP). A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow between the source and drain. In instances where the charge carriers are electrons, the FET is referred to as an n-channel device; and in instances where the charge carriers are holes, the FET is referred to as a p-channel device. Some FETs have a fourth terminal called the body or substrate, which can be used to bias the transistor. In addition, metal-oxide-semiconductor FETs (MOSFETs) include a gate dielectric between the gate and the channel. MOSFETs may also be known as metal-insulator-semiconductor FETs (MISFETSs) or insulated-gate FETs (IGFETs). Complementary MOS (CMOS) structures use a combination of p-channel MOSFET (PMOS) and n-channel MOSFET (NMOS) devices to implement logic gates and other digital circuits.

A FinFET is a MOSFET transistor built around a thin strip of semiconductor material (generally referred to as a fin). The conductive channel of the FinFET device resides on the outer portions of the fin adjacent to the gate dielectric. Specifically, current runs along/within both sidewalls of the fin (sides perpendicular to the substrate surface) as well as along the top of the fin (side parallel to the substrate surface). Because the conductive channel of such configurations includes three different planer regions of the fin (e.g., top and two sides), such a FinFET design is sometimes referred to as a tri-gate transistor. A gate-all-around (GAA) transistor (sometimes referred to as a nanoribbon or nanowire transistor) is configured similarly to a fin-based transistor, but instead of a finned channel region, one or more channel bodies such as nanoribbons or nanowires extend between the source and the drain regions. In GAA transistors, the gate material wraps around each nanoribbon (hence, gate-all-around).

### BRIEF DESCRIPTION OF THE DRAWINGS

FIG. 1A illustrates a cross-section view of an integrated circuit structure including an upper device vertically stacked on a lower device, wherein the upper device comprises (i) a first layer including silicide, germanide, and/or germanosilicide of a first metal, the first layer adjacent to a source region of the upper device and (ii) a second layer including silicide, germanide, and/or germanosilicide of the first metal, the second layer adjacent to a drain region of the upper device, wherein the lower device comprises (i) a third layer including silicide, germanide, and/or germanosilicide of a second metal different from the first metal, the third layer adjacent to a source region of the upper device and (ii) a fourth layer including silicide, germanide, and/or germanosilicide of the second metal, the fourth layer adjacent to a drain region of the upper device, in accordance with an embodiment of the present disclosure.

FIG. 1B illustrates a cross-section view of an integrated circuit structure that is at least in part similar to the integrated circuit structure of FIG. 1A, where unlike the integrated circuit structure of FIG. 1A, the integrated circuit structure of FIG. 1B comprises a continuous drain contact for both the upper device and the lower device, in accordance with an embodiment of the present disclosure.

FIG. 1C illustrates a cross-section view of an integrated circuit structure that is at least in part similar to the integrated circuit structure of FIG. 1A, where unlike the integrated circuit structure of FIG. 1A, in the integrated circuit structure of FIG. 1B an upper gate electrode is separated from a corresponding lower gate electrode by a corresponding isolation region, in accordance with an embodiment of the present disclosure.

FIGS. 2A and 2B illustrate a flowchart depicting a method of forming the example nanoribbon semiconductor structure of FIG. 1A, in accordance with an embodiment of the present disclosure.

FIGS. 3A, 3B, 3C, 3D, 3E, 3F, 3F1, 3G, 3G1, 3H, 3I, 3J, 3K, 3L, 3M, and 3N collectively illustrate cross-sectional views of an example semiconductor structure (e.g., the semiconductor structure of FIG. 1A) in various stages of processing, in accordance with an embodiment of the present disclosure.

FIG. 4 illustrates a computing system implemented with integrated circuit structures formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles, and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

A vertically stacked transistor architecture is disclosed that includes an upper device and a lower device, where the upper device includes silicide, germanide, and/or germanosilicide of a first metal adjacent to its source and drain regions, and the lower device includes silicide, germanide, and/or germanosilicide of a second metal adjacent to its source and drain regions, and where the first metal and the second metal are elementally different, e.g., have different work functions. Note that the silicide, germanide, and/or germanosilicide is effectively between a source or drain contact and a corresponding source or drain region. For example, one of the upper or lower devices is a PMOS device, and the other of the upper or lower devices is an NMOS device. In an example, the metal of the silicide, germanide, and/or germanosilicide layer of a device is selected such that the band edge work function of the metal better matches to the device type. For example, a PMOS band edge work function metal is used for the silicide, germanide, and/or germanosilicide layer of the PMOS device, and an NMOS band edge work function metal is used for the silicide, germanide, and/or germanosilicide layer of the NMOS device. This facilitates in reducing contact resistance between the source or drain contact and the corresponding source or drain region of the respective PMOS and NMOS devices. In an example, a high work function metal may be used in the PMOS device, and a low work function metal may be used in the NMOS device. In an example, the PMOS device includes silicide, germanide, and/or germanosilicide of one or more of nickel, platinum, molybdenum, niobium, cobalt, tungsten, rhenium, rhodium, or iridium. In an example, the NMOS device includes silicide, germanide, and/or germanosilicide of one or more of titanium, aluminum, gadolinium, erbium, or scandium.

In one embodiment, an integrated circuit structure comprises a second device stacked vertically above a first device. The first device comprises (i) a first source or drain region, (ii) a first source or drain contact coupled to the first source or drain region, and (iii) a first layer comprising a first metal and first one or more semiconductor materials between at least a section of the first source or drain region and the first source or drain contact. In an example, the first layer is a silicide, germanide, and/or germanosilicide of the first metal. The second device comprises (i) a second source or drain region, (ii) a second source or drain contact coupled to the second source or drain region, and (iii) a second layer comprising a second metal and second one or more semiconductor materials between at least a section of the second source or drain region and the second source or drain contact. Note that “coupled to” as used does not require a direct contact; rather, such coupling may be accomplished by one or more intervening layers, and in this example case one or more layers of silicide, germanide, and/or germanosilicide. In an example, the second layer is a silicide, germanide, and/or germanosilicide of the second metal. In an example, the first metal and the second metal are elementally different, and may have different work functions (e.g., one having p-type work function and the other having n-type work function). In an example, one of the first and second devices is a PMOS device and the other of the first and second devices is an NMOS device. The first and second metals have band edge work function matched or otherwise suitable to respective ones of the PMOS or NMOS device. In an example, the PMOS device includes silicide, germanide, and/or germanosilicide of one or more of nickel, platinum, molybdenum, niobium, cobalt, tungsten, rhenium, rhodium, or iridium. In an example, the NMOS device includes silicide, germanide, and/or germanosilicide of one or more of titanium, aluminum, gadolinium, erbium, or scandium.

In another embodiment, an integrated circuit structure comprises an upper device stacked vertically above a lower device. The lower device comprises (i) a first source (or drain) region, (ii) a first source (or drain) contact extending within the first source (or drain) region, and (iii) a first silicide and/or germanide layer comprising a first metal. In an example, the first silicide and/or germanide layer is between at least a section of the first source (or drain) region and the first source (or drain) contact. The upper device comprises (i) a second source (or drain) region above the first source (or drain) region, (ii) a second source (or drain) contact extending within the second source (or drain) region, and (iii) a second silicide and/or germanide layer comprising a second metal. In an example, the second silicide and/or germanide layer is between at least a section of the second source (or drain) region and the second source (or drain) contact. In an example, a work function of the first metal is different from a work function of the second metal. In an example, the first metal is elementally different from the second metal. In an example, an isolation structure is between the first source (or drain) region and the second source (or drain) region. In an example, the isolation structure is also between the first source (or drain) contact and the second source (or drain) contact.

In yet another embodiment, an integrated circuit structure comprises an upper transistor device vertically stacked above a lower transistor device. In an example, the upper transistor device comprises first one or more silicide and/or germanide layers in contact with an upper source region and/or an upper drain region of the upper device, and the lower transistor device comprises second one or more silicide and/or germanide layers in contact with a lower source region and/or a lower drain region of the lower device. In an example, the first one or more silicide and/or germanide layers comprise a first metal that is elementally different from a second metal of the second one or more silicide and/or germanide layers.

Note that, in any of the examples provided herein, a given layer of silicide, germanide, and/or germanosilicide may effectively be at least partially integrated into a given source or drain region and/or a given source or drain contact, given the reactive process that may be used to form that layer. In any such cases, the layer of silicide, germanide, and/or germanosilicide may still be discernible from the related diffusion region (source or drain region) and the contact. Numerous configurations and variations will be apparent in light of this disclosure.

### General Overview

Integrated circuitry continues to scale to smaller feature dimensions and higher transistor densities. As a result, a gate pitch, as well as a pitch for source and drain contacts, continue to reduce. With such tight pitch and smaller contact size, contact resistance between a source or drain contact and the corresponding source or drain region tends to increase. So, in a vertically stacked transistor architecture having an upper device above a lower device, it may be desirable to reduce contact resistances in the source and drain regions of the upper and lower devices. To this end, a conductive layer can be provided between a source or drain contact and a corresponding source or drain region of each of the upper and lower devices, where the layer comprises metal silicide (comprising the metal and silicon), metal germanide (comprising metal and germanium), and/or metal germanosilicide (comprising metal, Si and Ge), where the layer reduces contact resistances between the source or drain contact and the corresponding source or drain region. In an example, one of the upper or lower devices is a PMOS device, and the other of the upper or lower devices is a NMOS device. However, due to the use of the same metal in both the PMOS and NMOS devices, contact resistivity of either the PMOS or the NMOS device may suffer, depending upon which band edge or work function metal is chosen for the silicide, germanide, and/or germanosilicide layers of the vertical stack.

Accordingly, techniques are provided herein to form an IC that includes a vertically stacked transistor architecture including an upper device above a lower device, where the upper device has upper layers adjacent to upper source and drain regions of the upper device, and the lower device has lower layers adjacent to lower source and drain regions of the lower device, and where the upper layers comprise silicide, germanide, and/or germanosilicide of first one or more metals, where the lower layers comprise silicide, germanide, and/or germanosilicide of second one or more metals, and where the first and second one or more metals are elementally different, e.g., have diverse or otherwise different work functions. For example, one of the upper or lower devices is a PMOS device, and the other of the upper or lower devices is an NMOS device. In an example, the one or more metals of the layers of a device is selected such that the work function of the one or more metals better matches to the device type. For example, one or more PMOS band edge work function metals may be used for the silicide, germanide, and/or germanosilicide layer of the PMOS device, and NMOS band edge work function metals may be used for the silicide, germanide, and/or germanosilicide layer of the NMOS device. This facilitates in reducing contact resistance between the source or drain contact and the corresponding source or drain region of each of the PMOS and NMOS devices. As an example, a high work function metal may be used in the layers of the PMOS device, and a low work function metal may be used in the layers of the NMOS device. In an example, the PMOS device includes silicide, germanide, and/or germanosilicide of one or more of nickel, platinum, molybdenum, niobium, cobalt, tungsten, rhenium, rhodium, or iridium. In an example, the NMOS device includes silicide, germanide, and/or germanosilicide of one or more of titanium, aluminum, gadolinium, erbium, or scandium.

In an example, the PMOS source and drain regions comprise SiGe doped with an appropriate p-type dopant (e.g., boron), and NMOS source and drain regions comprise silicon doped with an appropriate p-type dopant (e.g., phosphorus), although other semiconductor materials may also be used in the source or drain regions of the two devices. Thus, in the PMOS device in which the source and drain regions comprise SiGe, the corresponding layers may comprise silicide, germanide, and/or germanosilicide of the appropriate metal selected for the PMOS device. In an example, in the NMOS device in which the source and drain regions comprise Si, the corresponding layers may comprise silicide of the appropriate metal selected for the NMOS device.

Note that as an example, the upper and lower devices are assumed to be GAA devices that includes nanoribbons in the channel region. As will be appreciated in light of this disclosure, reference to nanoribbons as channel regions is also intended to include other gate-all-around or multi-gate channel regions, such as nanowires, nanosheets, and other such semiconductor bodies around which a gate structure can at least in part wrap. In another example, the techniques described herein may be applied to any vertically stacked transistor devices, in which the above discussed silicide (or germanide or germanosilicide) layers are used in the respective source and drain regions of the stacked transistors. To this end, the use of a specific channel region configuration (e.g., nanoribbon) is not intended to limit the present description to that specific channel configuration. Rather, the techniques provided herein can benefit any number of channel configurations, whether those bodies be nanowires, nanoribbons, nanosheets or some other body of semiconductor material around which a gate structure can at least partially wrap (such as the semiconductor bodies of a forksheet device or a fin-based device), or another appropriate type of transistor architecture.

In an example, to form the above discussed silicide (or germanide or germanosilicide) layers for source and drain regions of the upper and lower devices, one or more fins comprising alternating layers of sacrificial material and channel material are formed, followed by formation of dummy gate, source regions and drain regions. Then the nanoribbons are released by removing the dummy gate to expose the channel region and then selectively removing sacrificial material from exposed channel region. The gate stack can then be formed. Thus, a major portion of the NMOS and PMOS devices, except, for example, the respective source and drain contacts and the respective silicide (or germanide or germanosilicide) layers, are initially formed by these processes.

Note that in the stacked device architecture, the upper source region of the upper device and the lower source region of the lower device are at least in part vertically aligned (e.g., the upper source region is above the lower source region, and may or may not be separated from the lower source region by a corresponding isolation region). Similarly, the upper drain region of the upper device and the lower drain region of the lower device are at least in part vertically aligned (e.g., the upper drain region is above the lower drain region, and may or may not be separated from the lower drain region by a corresponding isolation region).

Subsequent discussions will focus on formation of the silicide (or germanide or germanosilicide) layers adjacent to the vertically aligned upper and lower source regions.

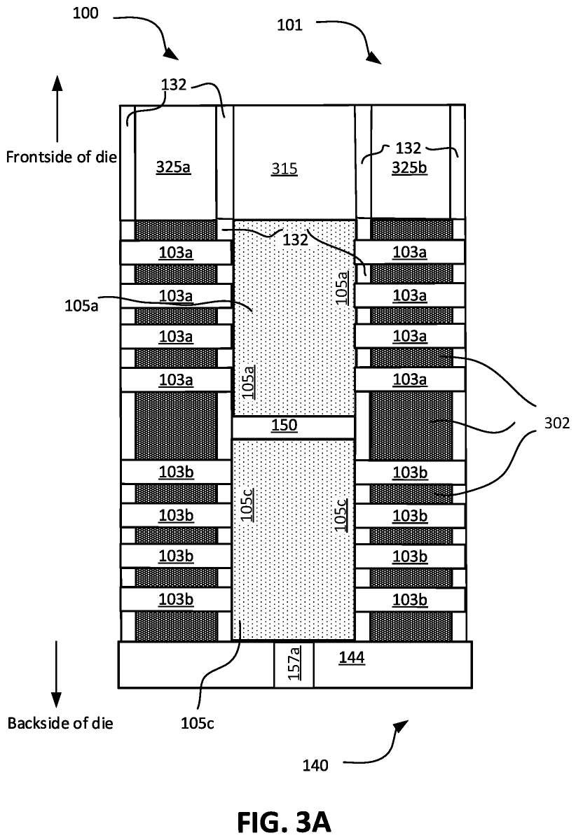

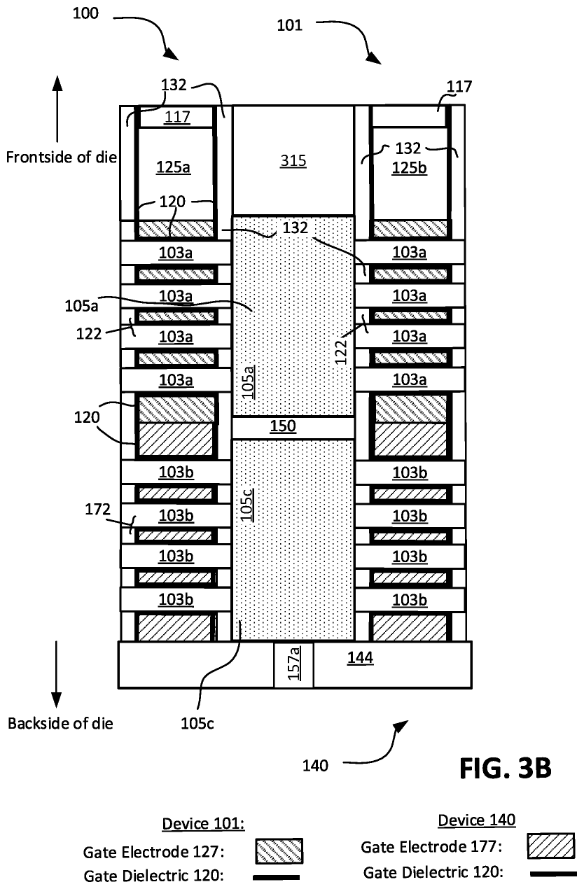

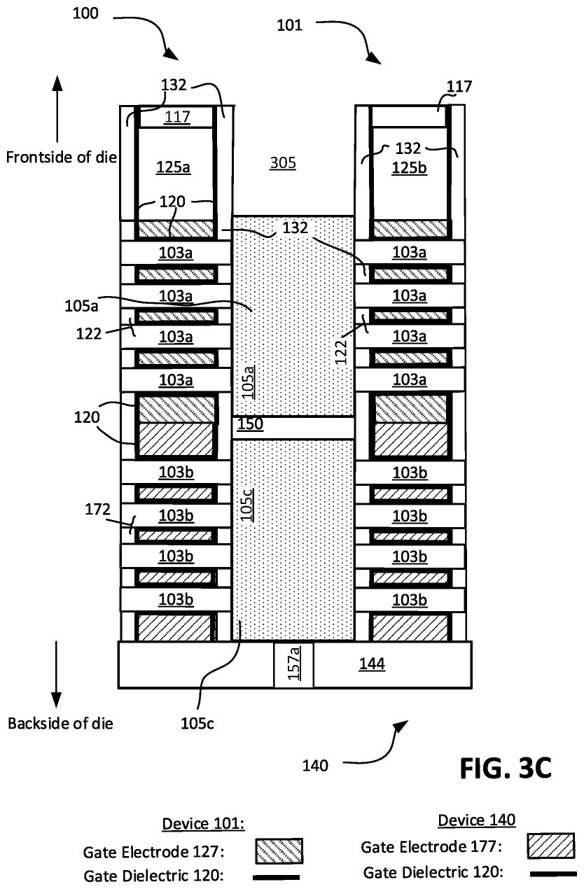

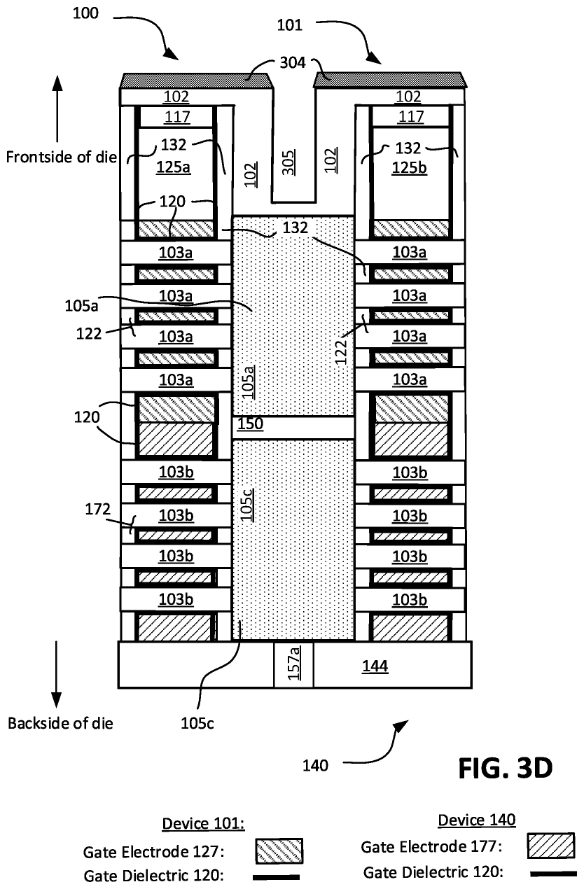

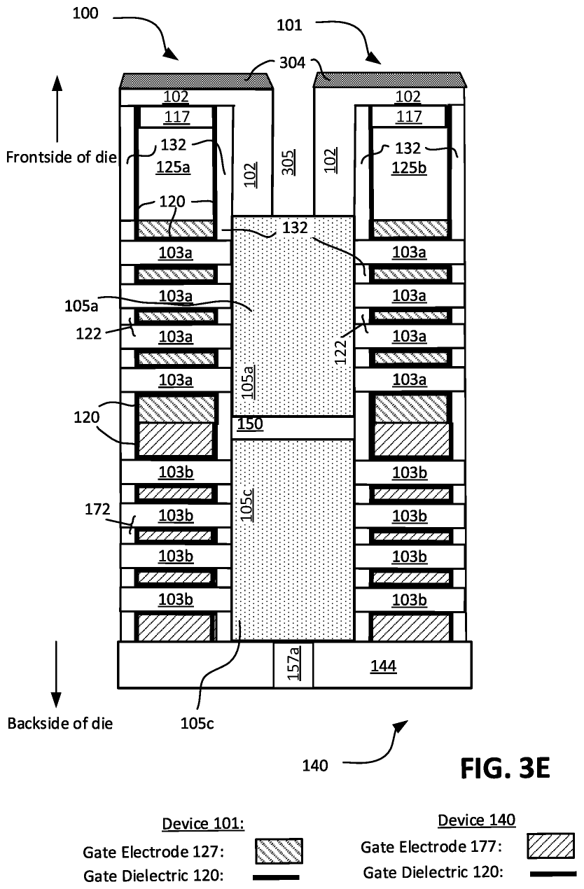

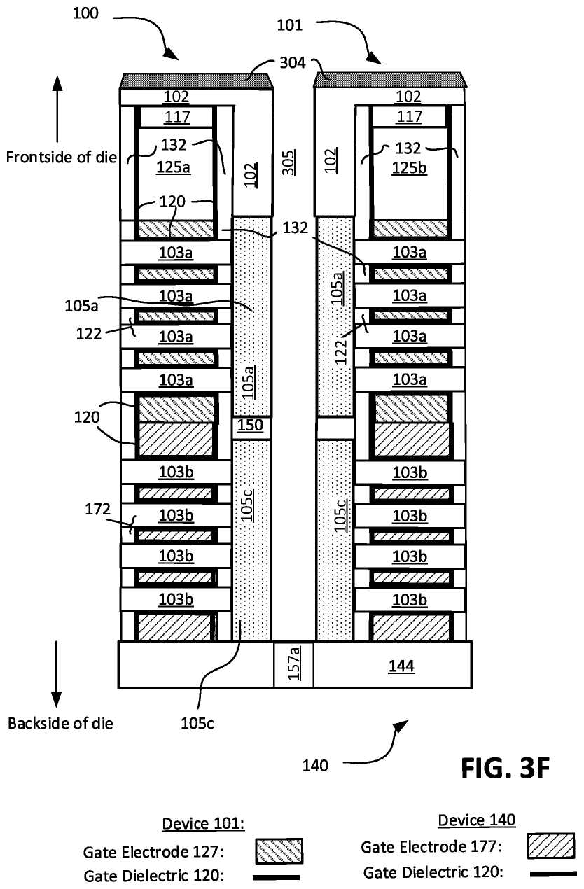

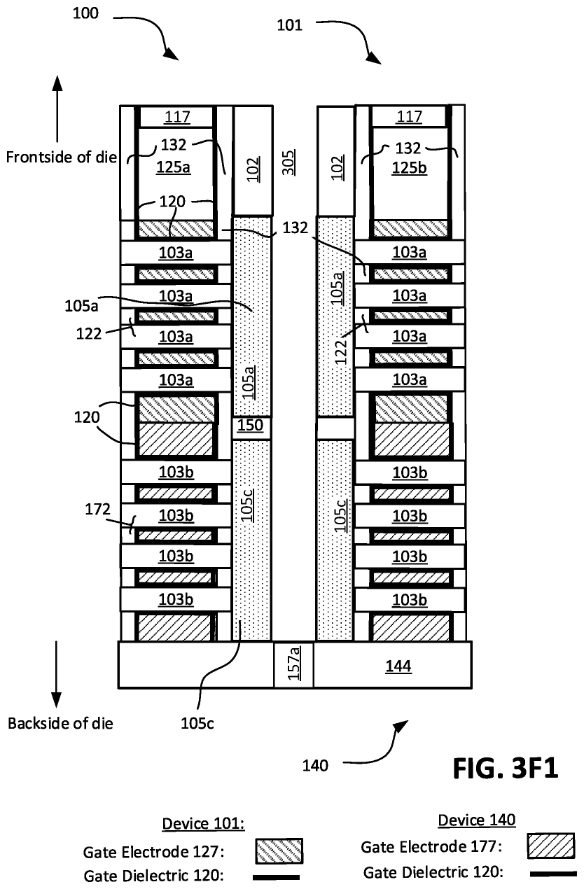

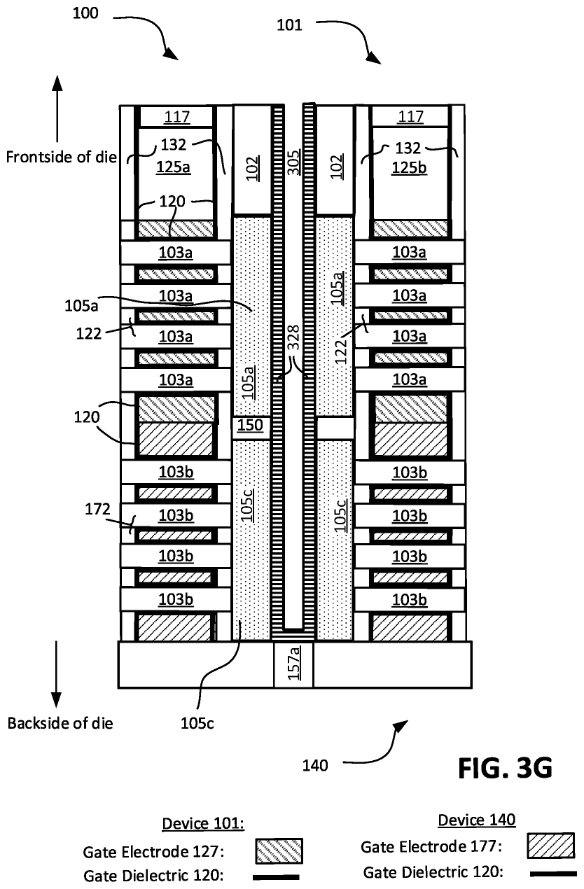

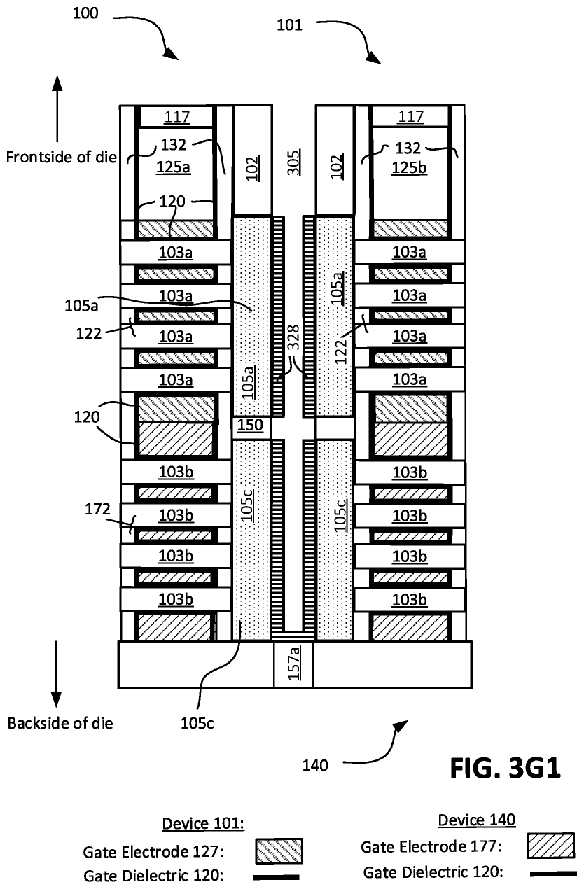

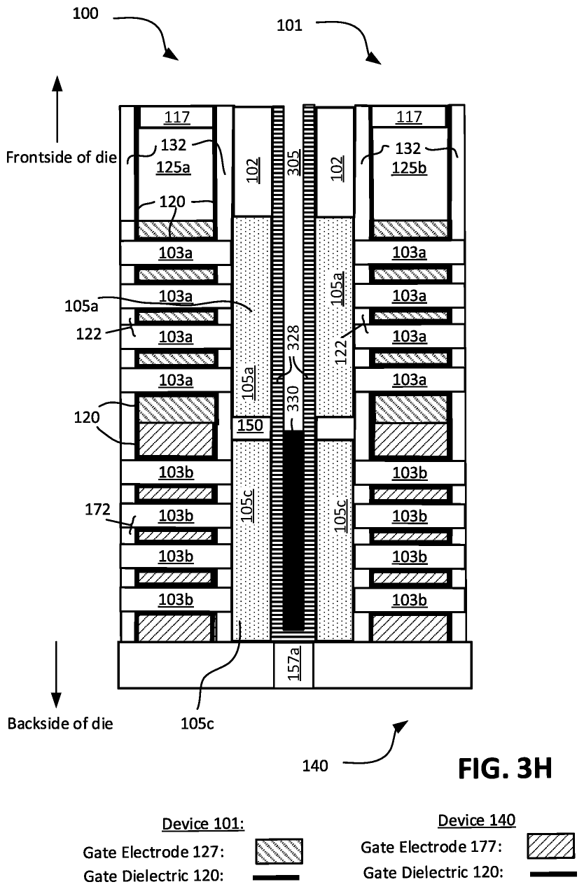

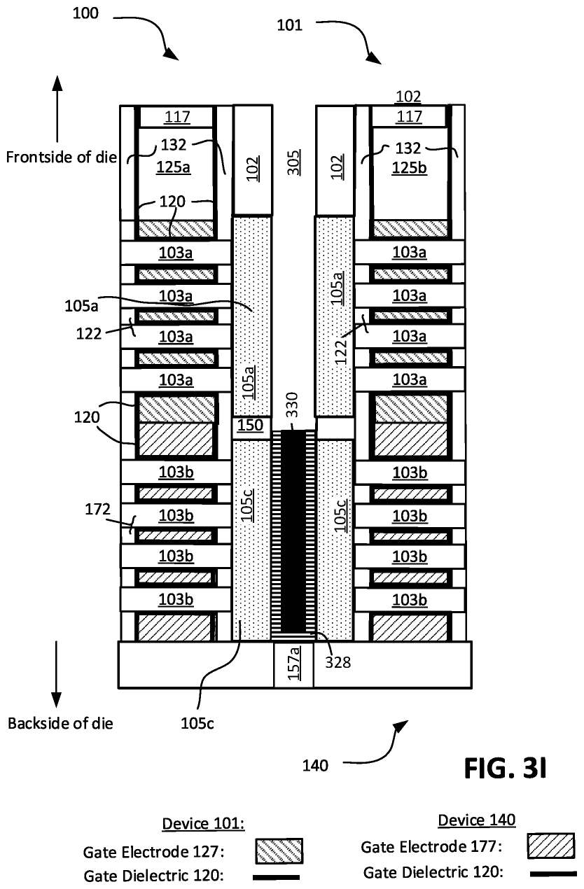

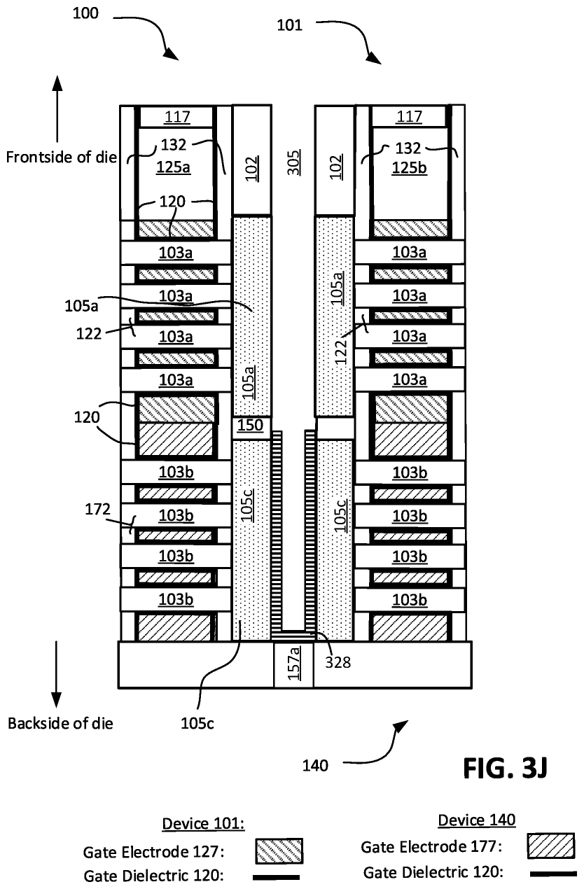

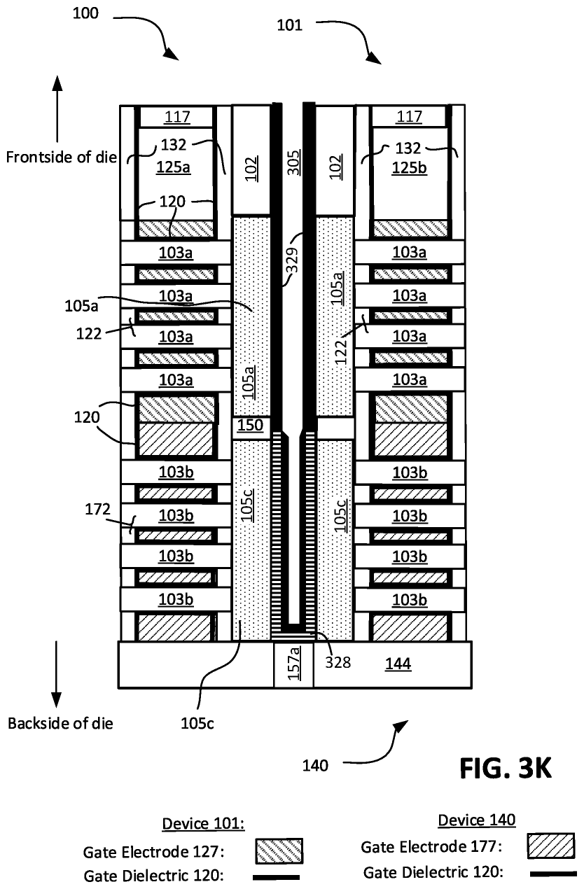

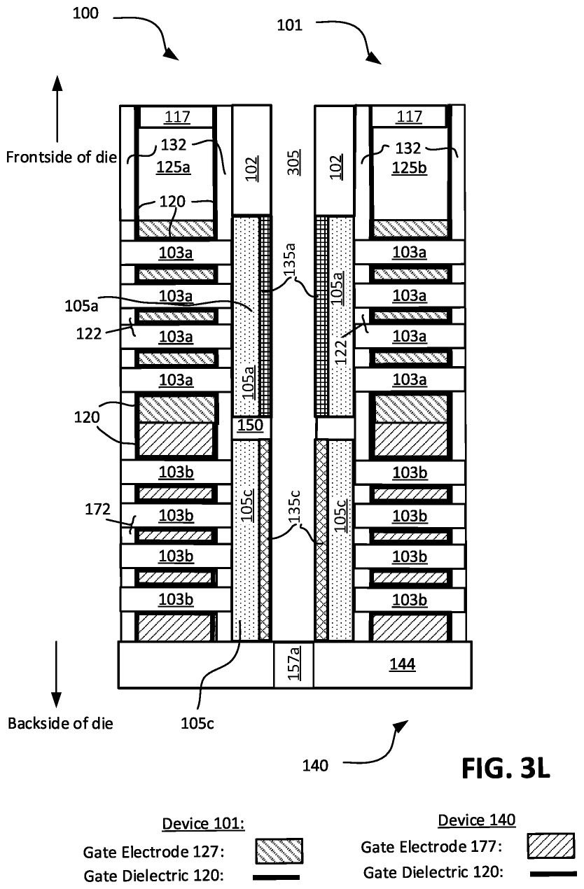

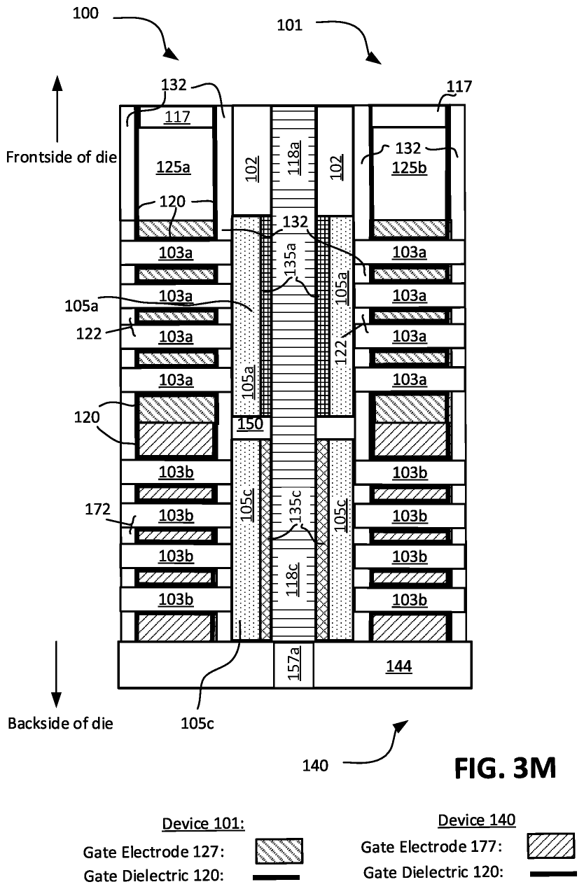

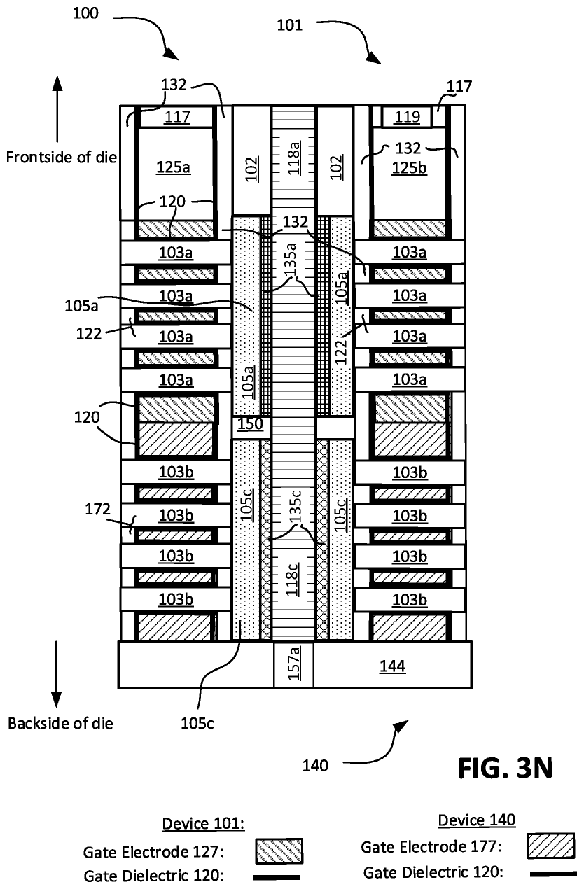

To form the silicide (or germanide or germanosilicide) layers in the upper and lower source regions, a layer of liner (e.g., comprising dielectric material, see FIG. 3E) is formed on walls of gate spacers and partially the upper source region of the upper device (note that the liner or liner layer is different from the silicide (or germanide or germanosilicide) layers discussed herein). The liner defines a recess or opening above a top surface of the upper source region. In an example, a thickness or width of the liner dictates a width of the opening, which in turn dictates the width of the source contacts to be eventually formed. In an example, the liner is etch-selective with respect to the material of the source regions of the upper and lower devices. For example, an etch process that etches the source regions may not substantially etch (or etch at a substantially slower rate) the liner. In some examples, a protective layer may also be deposited on top surfaces of the liner, which acts as a “helmet” in the sense that it protects the liner, e.g., when the recess within the source and drain regions are formed. Subsequently, portions of the upper and lower source regions of each of the upper and lower devices are removed through the opening defined by the liner, so as to extend the opening within the upper and lower source regions (e.g., as illustrated in FIG. 3F). Note that the opening now also extends through the isolation region between the upper and lower source regions. A selective anisotropic or directional etch may be performed, such that a rate of etching the source regions is substantially faster than a rate of etching the liner and/or the protective layer. Accordingly, after the etch process, the liner and the protective layer continue to cover the walls of the gate spacer and the gate electrode. Subsequently, the protective layer and at least a part of the liner is removed, such that, in an example, remnants of the liner is still on sidewalls of the upper gate spacers.

Subsequently, first one or more metals (that is suitable for forming the silicide (or germanide or germanosilicide) layers for the lower device) is deposited within the opening extending through the upper and lower source regions. An upper portion of the first one or more metals is on sidewalls of the upper source region, a lower portion of the first one or more metals is on sidewalls of the lower source region, and a middle portion of the first one or more metals is on sidewalls of the isolation region, e.g., see FIG. 3G. Subsequently, a hard mask is deposited on a bottom portion of the opening, such that the hard mask is on walls of the lower portion of the first one or more metals and at least in part of the middle portion of the first one or more metals. Upper portion and at least a part of the middle portion of the one or more first metals, which are not covered by the hard mask, are removed through a selective etch process that does not substantially etch the source regions and the hard mask. The hard mask is then removed, and the first one or more metals is now on sidewalls of the lower source region (and also partly on sidewalls of the isolation region), but not on sidewalls of the upper source region (e.g., see FIG. 3J).

Subsequently, second one or more metals (that is suitable for forming the silicide (or germanide or germanosilicide) layers for the upper device) is deposited within the opening extending through the upper and lower source regions. An upper portion of the second one or more metals is on sidewalls of the upper source region, and a lower portion of the second one or more metals is on inner walls of the first one or more metals, e.g., see FIG. 3K.

The first one or more metals and the second one or more metals are then processed (e.g., where the processing includes annealing at a high temperature to react the metal and semiconductor materials), to respectively form the upper silicide (or germanide or germanosilicide) layer adjacent to the upper source region and lower silicide (or germanide or germanosilicide) layer adjacent to the lower source region, e.g., see FIG. 3L. Any unreacted remnants of the first and second one or more metals are removed or etched, after formation of the silicide (or germanide or germanosilicide) layers.

For example, as the first one or more metals are adjacent to the sidewalls of the lower source region of the lower device, the first one or more metals react with the semiconductor material (e.g., Si and/or Ge) of the lower source region of the lower device, to form the lower layer comprising silicide, germanide, and/or germanosilicide of the first one or more metals. Note that the lower portion of the second one or more metals that may be on the inner walls of the first one or more metals (e.g., see FIG. 3K) are not adjacent to the lower source region of the lower device. Accordingly, the lower portion of the second one or more metals cannot react with the lower source region of the lower device. Thus, that lower portion of the second one or more metals on the inner walls of the first one or more metals remain unreacted, and can be readily removed (e.g., via selective etch process) after formation of the various silicide (or germanide or germanosilicide) layers. In an example, the lower device is a PMOS device in which the source and drain regions comprise SiGe, and the corresponding lower layer may comprise silicide, germanide, and/or germanosilicide of the first one or more metals (and not of the second one or more metals).

Similarly, as the second one or more metals are adjacent to the sidewalls of the upper source region of the upper device, the second one or more metals react with the semiconductor material (e.g., Si and/or Ge) of the upper source region of the upper device, to form the upper layer comprising silicide, germanide, and/or germanosilicide of the second one or more metals. Note that the first one or more metals are not adjacent to the upper source region of the upper device. Accordingly, the silicide, germanide, and/or germanosilicide of the upper layer of the upper device are of the second one or more metals (and not of the first one or more metals). In an example, the upper device is an NMOS device in which the source and drain regions comprise silicon, the corresponding layer may comprise silicide (and may be germanide, and/or germanosilicide) of the second one or more metals.

Subsequent to forming the lower and upper silicide, germanide, and/or germanosilicide layers, conductive material may be deposited within the opening extending within the upper and lower source regions, to respectively form the upper and lower source contacts. In another example, the conductive fill material can be provided before the annealing process, and a subsequent application of heat causes the silicide, germanide, and/or germanosilicide to form. In still another example, the silicide, germanide, and/or germanosilicide may form over a number of distinct heating processes that occur over a given time period and at different points in the fabrication process. To this end, the silicide, germanide, and/or germanosilicide need not be formed in single annealing process, and in some cases may be performed at some point after the contact fill metal(s) is deposited into the contact trench(s).

Note that in this example, the upper and lower source contacts, in combination, form a continuous and monolithic contact, which also extends through the isolation region between the upper and lower source regions. In an example, top portion of the deposited conductive materials may be planarized using an appropriate planarization technique, such as mechanical polishing or chemical-mechanical polishing (CMP). This completes formation of the upper and lower source contacts of the upper and lower devices, respectively.

Further note that while the upper and lower source contacts that are continuous in the above discussed example, in another example, the upper and lower drain contacts may be discontinuous. In the example where the drain contacts are continuous, the continuous and monolithic drain contacts may extend within both upper and lower devices, and may be formed similar to formation of the continuous source contacts. In another example where the upper and lower drain contacts are discontinuous (e.g., separated by the isolation region), the above discussed process for forming the source contact may be appropriately modified for the drain contacts. For example, the lower drain contact may be deposited from the frontside, followed by deposition of dielectric material of the isolation region, and the conductive material of the upper drain contact may be deposited, to form the discontinuous lower and upper drain contacts. In another example, the upper drain contact may be deposited from the frontside, and the lower drain contact may be deposited from the backside. This completes formation of the drain contacts of the upper and lower devices.

Note that as discussed herein, the upper device comprises silicide, germanide, and/or germanosilicide of first one or more metals, and the lower device comprises silicide, germanide, and/or germanosilicide of second one or more metals, and where the first and second one or more metals are elementally different. The dual silicidation process (e.g., the process to form the silicide, germanide, and/or germanosilicide in the upper and lower devices) discussed herein is a mask-less process, e.g., does not use a mask to protect a first device while the silicidation process is being performed on a second device, and/or does not use a mask to protect the second device while the silicidation process is being performed on the first device. Rather, the silicidation process in both upper and lower devices are performed, without needing to mask either the upper device or the lower device when performing the silicidation process.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, such tools be used to detect an upper device having upper layers comprising silicide, germanide, and/or germanosilicide of first one or more metals, where the upper layers are between upper source and drain regions and corresponding upper source and drain contacts, respectively. Such tools may also be used to detect a lower device having lower layers comprising silicide, germanide, and/or germanosilicide of second one or more metals, where the lower layers are between lower source and drain regions and corresponding lower source and drain contacts, respectively. In an example, the first and second one or more metals are elementally different, e.g., have diverse work functions, such as p-type and n-type work functions. Numerous configurations and variations will be apparent in light of this disclosure.

Architecture

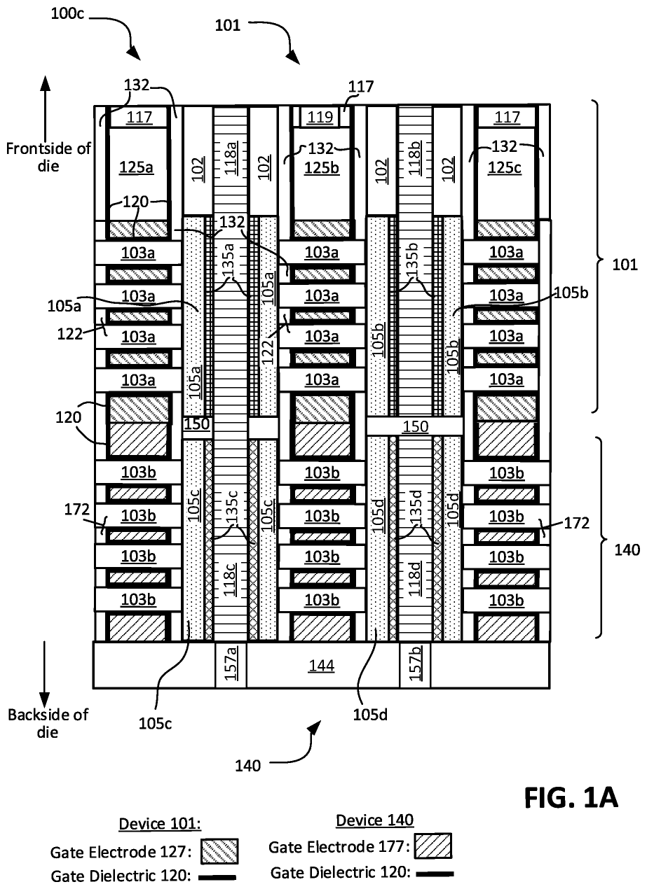

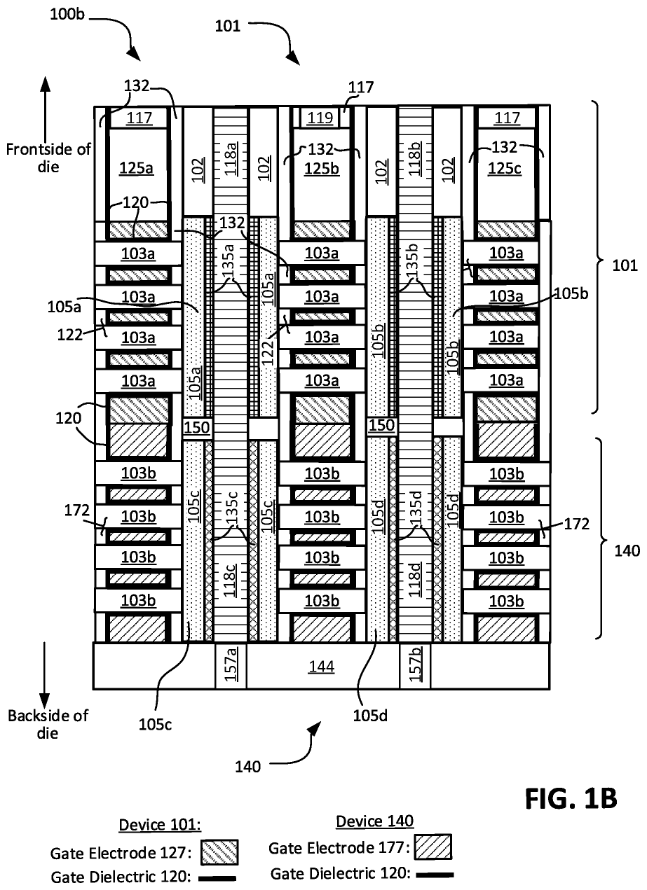

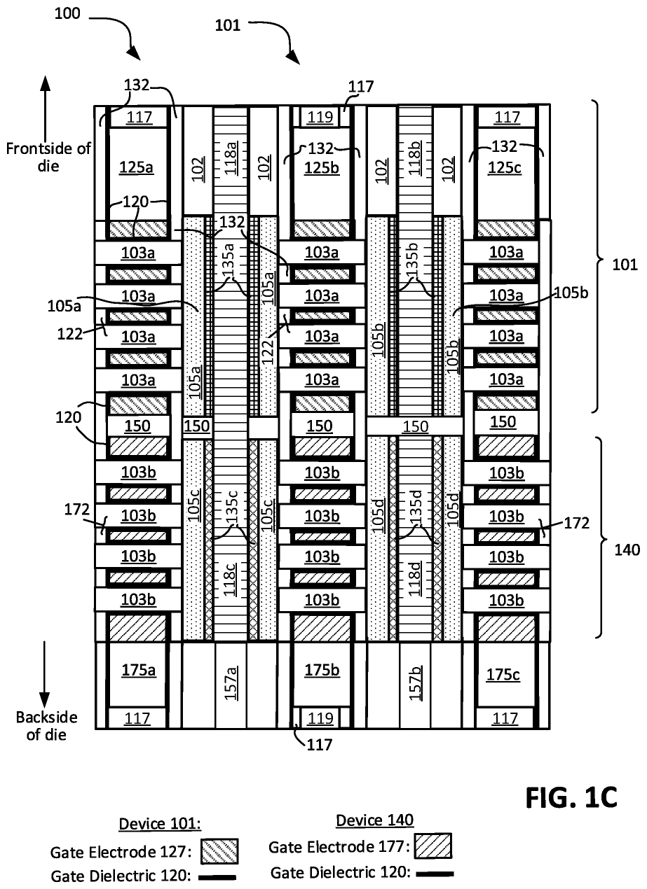

FIG. 1A illustrates a cross-section view of an integrated circuit structure 100 (also referred to herein as “structure 100”) including an upper device 101 vertically stacked on a lower device 140, wherein the upper device 101 comprises (i) a first layer 135a including silicide, germanide, and/or germanosilicide of a first metal, the first layer 135a adjacent to a source region 105a of the upper device 101 and (ii) a second layer 135b including silicide, germanide, and/or germanosilicide of the first metal, the second layer 135b adjacent to a drain region 105b of the upper device 101, wherein the lower device 140 comprises (i) a third layer 135c including silicide, germanide, and/or germanosilicide of a second metal different from the first metal, the third layer 135c adjacent to a source region 105c of the upper device 140 and (ii) a fourth layer 135d including silicide, germanide, and/or germanosilicide of the second metal, the fourth layer 135d adjacent to a drain region 105d of the upper device 140, in accordance with an embodiment of the present disclosure.

As can be seen, the cross-section of FIG. 1A is taken parallel to, and through, the fin structure, such that the channel, source, and drain regions are shown. This particular cross-section includes three channel regions along with a source region and a drain region for each device 101, 140, but any number of channel regions and corresponding source and drain regions can be included, as will be appreciated. Further note that all devices shown in this example are contacted, but other examples may include dummy devices or devices that are not connected into the overall circuit. The semiconductor bodies 103a and 103b included in the channel regions of the devices 101 and 140, respectively, can vary in form, but in this example embodiment are in the form of nanoribbons. In particular, the channel regions of the upper device 101 in this example case include a first set of four nanoribbons 103a, and the channel regions of the lower device 140 include a second set of four nanoribbons 103b. Other examples may include fewer nanoribbons per channel region (e.g., one or two), or more nanoribbons per channel region (e.g., five or six). Still other embodiments may include other channel configurations, such as one or more nanowires or a fin or other semiconductor body, including both planar and nonplanar topologies. To this end, the present disclosure is not intended to be limited to any particular channel configuration or topology; rather the techniques provided herein can be used in any transistor architecture that uses complementary type of vertically stacked transistors.

In the example of FIG. 1A, the upper device 101 includes a source region 105a and a drain region 105b, each adjacent to a gated channel region on either side. Other embodiments may not have gated channel regions to each side, such as the example case where only the channel region between source region 105a and drain region 105b is present. The lower device 140 includes a source region 105c and a drain region 105d, each adjacent to a gated channel region on either side. Other embodiments may not have gated channel regions to each side, such as the example case where only the channel region between source region 105c and drain region 105d is present. Note that in an example, the location of the source and drain regions in one or both devices may be interchanged. For example, while the regions 105a and 105b are respectively identified as being a source region and a drain region, in another example, the regions 105a and 105b may be a drain region and a source region, respectively. Similarly, in an example, while the regions 105c and 105d are respectively identified as being a source region and a drain region, in another example, the regions 105c and 105d may be a drain region and a source region, respectively. For example, each of the regions 105a, 105b, 105c, 105d can be any of a source region or a drain region (e.g., as long as each of the upper device 101 and the lower device 140 has one source region and one drain region). For purposes of this disclosure, each of the regions 105a, 105b, 105c, 105d is also referred to herein as a “source or drain region.”

Although not illustrated in FIG. 1A, in an example, the source region 105a of the upper device 101 may include a nucleation region adjacent to the nanoribbons 103, and an epitaxially formed main region adjacent to the nucleation region, where a doping concentration of the main region may be higher than that of the nucleation region. Each of the other source and drain regions 105b, 105c, 105d may also similarly have a corresponding nucleation region and a main region. In some examples, the nucleation regions may be absent. Numerous source and drain configurations can be used, and the present disclosure is not intended to be limited to any particular ones.

In some example embodiments, the source and drain regions 105a, 105b, 105c, 105d are epitaxial source and drain regions that are provided after the relevant portion of the fin or fin structure was isolated and etched away or otherwise removed. In other embodiments, the source/drain regions may be doped portions of the fin structure or substrate, rather than epi regions. In some embodiments using an etch and replace process, the epi source and drain regions are faceted and overgrown from a trench within insulator material (e.g., shallow trench isolation, or gate spacer 132 that deposits on the sides of the fin structure in the source and drain locations), and the corresponding source or drain contact structure lands on that faceted portion. Alternatively, in other embodiments, the faceted portion of epi source and drain regions can be removed (e.g., via chemical mechanical planarization, or CMP), and the corresponding source or drain contact structure lands on that planarized portion.

The source and drain regions can be any suitable semiconductor material and may include any dopant scheme. In an example, source and drain regions can be PMOS source and drain regions that include, for example, group IV semiconductor materials such as silicon, germanium, SiGe, germanium tin (GeSn), SiGe alloyed with carbon (SiGe:C). Example p-type dopants include boron, gallium, indium, and aluminum. Source and drain regions can be NMOS source and drain regions that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. Example n-type dopants include phosphorus, bismuth, antimony, arsenic, lithium, and tellurium. In one specific embodiment, PMOS source and drain regions are boron-doped SiGe, and NMOS source and drain regions are phosphorus-doped silicon. In a more general sense, the source and drain regions can be any semiconductor material suitable for a given application.

In some cases, the epi source and drain regions may include a multilayer structure, such as a germanium cap on a SiGe body, or a germanium body and a carbon-containing SiGe spacer or liner between the corresponding channel region and that germanium body. In any such cases, a portion of the epi source and drain regions may have a component that is graded in concentration, such as a graded germanium concentration to facilitate lattice matching, or a graded dopant concentration to facilitate low contact resistance. Any number of source and drain configurations can be used as will be appreciated, and the present disclosure is not intended to be limited to any particular such configurations.

In an example, the source region 105a is separated from the source region 105c by an isolation region 150, the drain region 105b is separated from the drain region 105d by another isolation region 150. The isolation region 150 comprises non-conductive material or dielectric material, such as oxides, nitrides, carbides, oxynitrides, oxycarbides, and oxycarbonitrides.

As illustrated in FIG. 1A, for the upper device 101, a source contact 118a extends within the source region 105a, and a drain contact 118b extends within the drain region 105b. Similarly, for the lower device 140, a source contact 118c extends within the source region 105c, and a drain contact 1218d extends within the drain region 105d.

As illustrated, the source contact 118a of the upper device 101 is above and at least in part aligned with the source contact 118c of the lower device 140. For example, an imaginary vertical line passes through both the source contact 118a and the source contact 118c. As illustrated, the imaginary vertical line is perpendicular to a length of the horizontal nanoribbons 103. Similarly, as illustrated, the drain contact 118b of the upper device 101 is above and at least in part aligned with the drain contact 118d of the lower device 140. For example, another imaginary vertical line (e.g., perpendicular to a length of the horizontal nanoribbons 103) passes through both the drain contact 118a and the drain contact 118c.

In the example of FIG. 1A, the source contacts 118a and 118c are in contact through the isolation region 150. Thus, in the example of FIG. 1A, the source contacts 118a and 118c form a common and continuous contact for both sources 105a and 105c. In the example of FIG. 1A, the drain contacts 118b and 118d are not in contact with each other, and are separated by the isolation region 150. Whether the source contact 118a of the upper device 101 and the source contact 118c of the lower device 140 (or the drain contact 118b of the upper device 101 and the drain contact 118d of the lower device 140) are to be in contact or not depends on a design or application of a circuit that includes the devices 101, 140. Thus, in another example, the source contact 118a of the upper device 101 and the source contact 118c of the lower device 140 may be separated by the corresponding isolation region. Similarly, in another example (e.g., see FIG. 1B), the drain contact 118b of the upper device 101 and the drain contact 118d of the lower device 140 may be in contact and may form a common and continuous contact.

In an example, a conductive layer 135 is between a source or drain contact and a corresponding source or drain region. For example, the conductive layer 135a is between the source contact 118a and the source region 105a, the conductive layer 135b is between the drain contact 118b and the drain region 105b, the conductive layer 135c is between the source contact 118c and the source region 105c, and the conductive layer 135d is between the drain contact 118d and the drain region 105d, as illustrated in FIG. 1A.

In an example, each of the conductive layers 135a, 135b, 135c, 135d is representative of Si-based silicides, Ge-based germanides, and/or SiGe-based germanosilicide between the conductive source or drain metal contact and the adjacent source or drain region. In an example, the layers 135 reduces contact resistance of the source and drain contacts.

In an example, the source and drain regions of the upper and lower devices 101, 140 comprise semiconductor material such as Si, Ge, SiGe. In an example, one of the devices 101 and 140 is a PMOS device, and the other of the devices 101 and 140 is an NMOS device. In an example, the PMOS source and drain regions comprise SiGe doped with an appropriate p-type dopant, and NMOS source and drain regions comprise silicon doped with an appropriate p-type dopant. Thus, in the PMOS device in which the source and drain regions comprise SiGe, the corresponding layers 135 may comprise silicide, germanide, and/or germanosilicide. In an example, in the NMOS device in which the source and drain regions comprise Si, the corresponding layers 135 may comprise silicide.

For example, assume that the upper device 101 is an NMOS device and the lower device 140 is a PMOS device (although in another example, the devices 101 and 140 can respectively be a PMOS and an NMOS device). Thus, in such an example, the layers 135a, 135b of the upper NMOS device 101 comprises silicide; and the layers 135c, 135d of the lower PMOS device 101 comprises silicide, germanide, and/or germanosilicide. In an example, the silicide, germanide, and/or germanosilicide of the layers 135 comprise a metal and one or both of silicon and germanium. For example, the silicide comprises a corresponding metal and silicon; the germanide comprises a corresponding metal and germanium; and the germanosilicide comprises a corresponding metal, silicon, and germanium.

In an example, a first metal is used for the layers 135a, 135b of the upper device 101, and a second metal is used for the layers 135c, 135d of the lower device 140. For example, as discussed herein, one of the devices 101 and 140 is a PMOS device, and the other of the devices 101 and 140 is an NMOS device. Thus, a one metal is used for the layers 135 of the PMOS device and another metal is used for the layers 135 of the NMOS device, e.g., to match the band edge work function requirements of a p-type source or drain region of the PMOS device and band edge the work function requirements of a n-type source or drain region of the NMOS device. Thus, a dual silicidation process is employed (e.g., as will be discussed herein later in turn) to form the layers 135a, 135b of the upper device 101 having first one or more metals, and the layers 135c, 135d of the lower device 140 having second one or more metals different from the first one or more metals. Thus, the metals of the layers 135 can be tailored or tuned to the particular type of PMOS or NMOS device for which the layers 135 are being formed. For example, the band edge work function of the metal(s) of the corresponding layer 135 can be matched with either the p-type or n-type source or drain region of a specific device.

In an example, one or more metals used for the layers 135 of a specific device can be selected to configure or tune the work function to the particular device. In an example, a high work function metal may be used within the layers 135 of the PMOS device, and a low work function metal may be used within the layers 135 of the NMOS device. In an example, the layers 135 of the PMOS device (e.g., where the layers 135 of the PMOS device comprises silicide, germanide, and/or germanosilicide) includes one or more of nickel, platinum, molybdenum, niobium, cobalt, tungsten, rhenium, rhodium, or iridium. For example, if nickel is used for the layers 135 of the PMOS device, then the layers 135 of the PMOS device may include nickel silicide, nickel germanide, and/or nickel germanosilicide.

In an example, the layers 135 of the NMOS device (e.g., where the layers 135 of the NMOS device comprises silicide) includes one or more of titanium, aluminum, gadolinium, erbium, or scandium. For example, if titanium is used for the layers 135 of the NMOS device, then the layers 135 of the NMOS device may include titanium silicide.

In an example and as would be discussed in further detail herein, the silicidation processes (which herein refers to the process of forming silicides, germanides, and/or germanosilicides of the layers 135, where the silicidation processes include annealing deposited metals) for both upper and lower devices may occur at least in part simultaneously.

In one embodiment, each of gate structures 122 of the upper device 101 wraps around each of the nanoribbons 103a in the corresponding channel region. Gate spacers 132 isolates the gate structures 122 from contacting the source region 105a and the drain region 105b. In other embodiments, there may be other insulator layers (e.g., interlayer dielectric) that prevent such contact, whether in addition to the gate spaces 132, or in place of the gate spacers 132. In an example, conductive gate contacts 125a, 125b, and 125c provide contacts to respective three gate structures 122 of the device 101. In an example, dielectric material 117 are above individual gate contacts 125a, 125b, 125c. In this example, none of the gate contacts 125a or 125b have been opened for being coupled to external circuit, as the gate contacts 125a, 125b are covered by the respectively dielectric material 117. In an example, the dielectric material 117 above the gate contact 125b is opened, e.g., such that a conductive via 119 extends through the dielectric material 117 and contacts the corresponding gate contact 125b. In another example, the dielectric material 117 above one or more of the gate contacts 125, 125b may also be opened, e.g., such that a conductive via (such as conductive via 119 over gate contact 172b) extends through the dielectric material 117 and contacts the corresponding gate contact 125.

In one embodiment, each of gate structures 172 of the lower device 140 wraps around each of the nanoribbons 103b in the corresponding channel region. Gate spacers 132 isolates the gate structures 172 from contacting the source region 166a and the drain region 166b. In other embodiments, there may be other insulator layers (e.g., interlayer dielectric) that prevent such contact, whether in addition to the gate spaces 132, or in place of the gate spacers 132.

Each of gate structures 122, 172 can be formed via gate-first or gate-last processing, and may include any number of suitable gate materials and configurations. In an embodiment, each of the gate structures 122, 172 includes a corresponding gate electrode and a gate dielectric 120 between the gate electrode and the corresponding nanoribbons 103. For example, each of the gate structures 122 of the upper device 101 comprises a corresponding gate electrode 127 and corresponding dielectric material 120. Each of the gate structures 172 of the lower device 140 comprises a corresponding gate electrode 177 and corresponding dielectric material 120. In one example the gate spacers 132 may be considered part of the gate structure, whereas in another example the gate spacers 132 may be considered external to the gate structure.

In the example of FIG. 1A, a lower gate electrode 177 and a corresponding upper gate electrode 127 are in direct contact with each other. For example, there is no isolation structure between the upper and lower gate electrodes, and both gate electrodes are accessed from the top or frontside of the die. However, in other examples, there may be a non-conductive isolation structure between a vertically stacked upper and lower gate electrodes, and in some such examples, the upper gate stack is accessed from the top or frontside, and where the lower gate stack is accessed from the bottom or backside.

In an example, the gate electrode 127 of the device 101 and the gate electrode 177 of the device 140 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example.

In one embodiment, one or more work function materials (not illustrated in FIG. 1A) may be included around the nanoribbons 103. Note that work function materials are called out separately, but may be considered to be part of the gate electrodes. In this manner, a gate electrode may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons 103. In still other embodiments, there may be insufficient room for any gate fill material, after deposition of work function material (i.e., a given gate electrode may be all work function material and no fill material). Numerous gate structure configurations can be used along with the techniques provided herein, and the present disclosure is not intended to be limited to any particular such configurations.

The gate dielectric material 120 (shown with thick bolded lines) warps around middle section of individual nanoribbons 103 (note that end sections of individual nanoribbons 103 are wrapped around by the gate spacers 132). The gate dielectric material 120 is between individual nanoribbons 103 and corresponding gate electrode, as illustrated. In an example, due to conformal deposition of the gate dielectric material 120, the gate dielectric material 120 may also be on inner sidewalls of the gate spacers 132, as illustrated.

The gate dielectric 120 may include a single material layer or multiple stacked material layers. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 120 is lanthanum. In some embodiments, the gate dielectric can be annealed to improve its quality when high-k dielectric material is used. In some embodiments, the gate dielectric 120 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer.

The semiconductor bodies 103a, 103b, which in this case are nanoribbons, can be any number of semiconductor materials as well, such as group IV material (e.g., silicon, germanium, or SiGe) or group III-V materials (e.g., indium gallium arsenide). In other embodiments, the semiconductor bodies 103 may be fins on which the corresponding gate structures are formed to provide double-gate or tri-gate configurations (as opposed to gate-all-around configurations with nanoribbons or wires). The semiconductor bodies 103 may be lightly doped, or undoped, and may be shaped or sculpted during the gate formation process, according to some embodiments. In some cases, semiconductor bodies 103 may be a multilayer structure, such as a SiGe body cladded with germanium, or a silicon body cladded with SiGe. Any number of channel configurations can be used.

In an example, the structure 100 is formed on a substrate 144. Embedded within the substrate 144 are a first conductive structure 157a below the source contact 118c of the lower device 140, and a second conductive structure 157b below the drain contact 118d of the lower device 140. In an example where the source and/or drain regions of the lower device 140 is to be coupled to outside circuits from the backside of the die, the conductive structures 157a, 157b may be respectively used for interconnections of the source and drain regions of the lower device 140. In an example, the conductive structures 157a, 157b may be absent.

FIG. 1B illustrates a cross-section view of an integrated circuit structure 100b (also referred to herein as “structure 100b”) that is at least in part similar to the integrated circuit structure 100 of FIG. 1A, where unlike the integrated circuit structure 100 of FIG. 1A, the integrated circuit structure 100b of FIG. 1B comprises a continuous drain contact for both the upper device 101 and the lower device 140, in accordance with an embodiment of the present disclosure. Thus, similar to the continuous source contact of the structure 100 of FIG. 1A, the drain contacts 118b and 118d of FIG. 1B form a continuous contact structure. As discussed, whether the source contact 118a of the upper device 101 and the source contact 118c of the lower device 140, and/or the drain contact 118b of the upper device 101 and the drain contact 118d of the lower device 140 are to be in contact or not depends on a design or application of a circuit that includes the devices 101, 140.

FIG. 1C illustrates a cross-section view of an integrated circuit structure 100c (also referred to herein as “structure 100c”) that is at least in part similar to the integrated circuit structure 100 of FIG. 1A, where unlike the integrated circuit structure 100 of FIG. 1A, in the integrated circuit structure 100b of FIG. 1B an upper gate electrode 127 is separated from a corresponding lower gate electrode 177 by a corresponding isolation region 150, in accordance with an embodiment of the present disclosure. Thus, similar to the isolation region 150 between the upper source region 105a and the lower source region 105c, the upper and lower gates are also isolated by the isolation region 150. In an example, the gate electrodes of the lower device 140 are accessed by lower gate electrodes 175a, 175b, 175c. In the example of FIG. 1C, the lower gate electrodes 175a, 175c are covered by corresponding dielectric material 117, and the dielectric material 117 below the lower gate electrode 175b is opened, and a conductive via 119 extends through the dielectric material 117 to contact the lower gate electrode 175b.

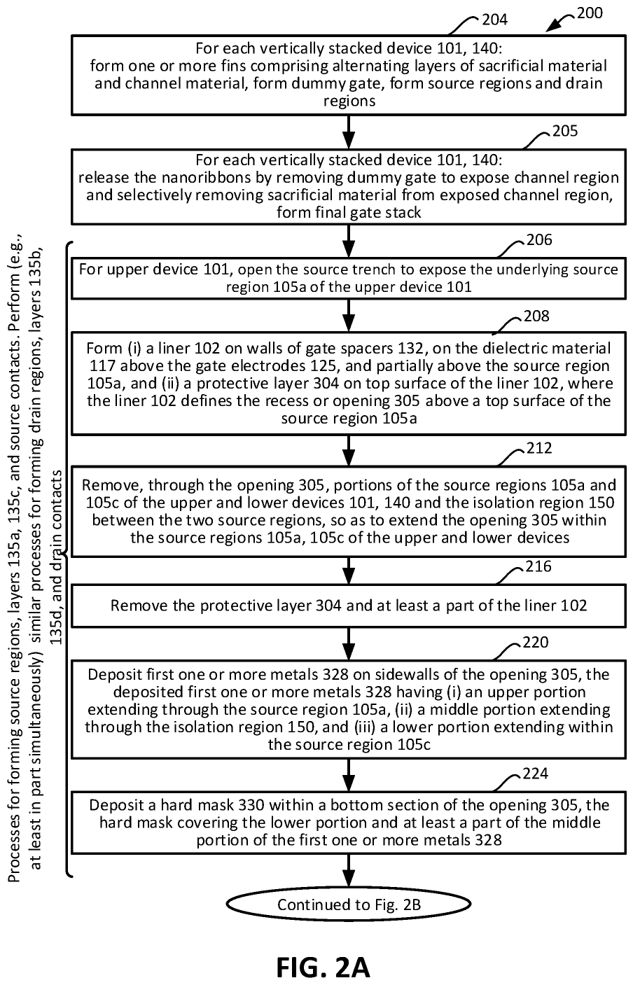

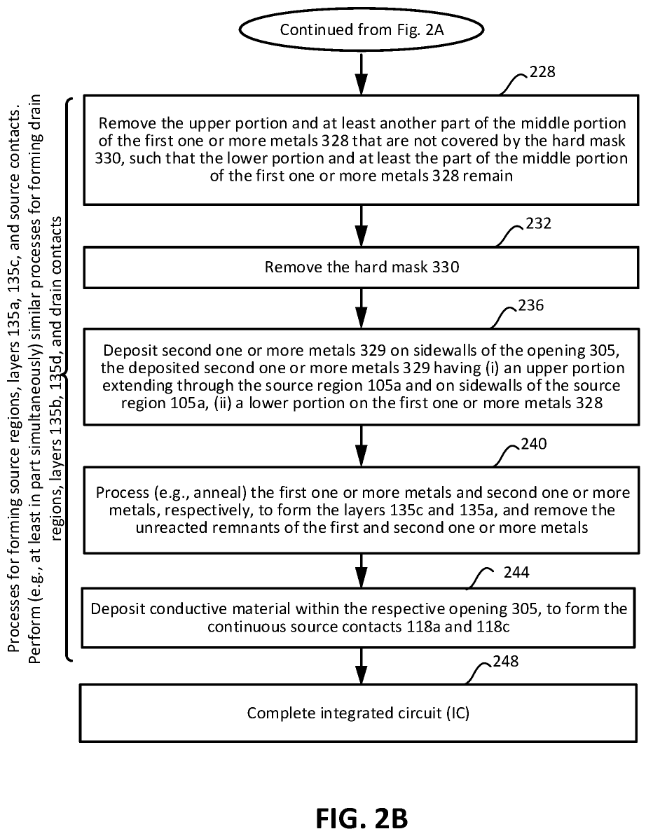

FIGS. 2A and 2B illustrate a flowchart depicting a method 200 of forming the example nanoribbon semiconductor structure 100 of FIG. 1A, in accordance with an embodiment of the present disclosure. FIGS. 3A, 3B, 3C, 3D, 3E, 3F, 3F1, 3G, 3G1, 3H, 3I, 3J, 3K, 3L, 3M, and 3N collectively illustrate cross-sectional views of an example semiconductor structure (e.g., the semiconductor structure 100 of FIG. 1A) in various stages of processing, in accordance with an embodiment of the present disclosure. FIGS. 2A-2B and 3A-3N will be discussed in unison. The cross-sectional views of FIGS. 3A-3N correspond to the cross-sectional view of FIG. 1A.

Note that FIGS. 3A-3N merely illustrate a portion of the structure 100 of FIG. 1A. For example, FIGS. 3A-3N illustrate formation of the source contact 118a extending within the source region 105a of the upper device 101 and formation of the source contact 118c extending within the source region 105c of the lower device 140. Similarly, the various processes illustrated in the method 200 of FIG. 2A are for forming the source regions 105a, 105b, the layers 135a, 135c, and the source contacts 118a, 118c. At least in part similar processes may also be performed at least in part in parallel for forming drain regions 105b, 105d, the layers 135b, 135d, and drain contacts 118b, 118d.

Referring to FIG. 2A, the method 200 includes, at 204, for each of the vertically stacked device 101 and 140, forming one or more fins comprising alternating layers of sacrificial material 302 and channel material 103, forming dummy gate (e.g., which includes dummy gate electrode 325a, 325b), and forming source regions and drain regions, e.g., as illustrated in FIG. 3A. As discussed, FIG. 3A illustrates the source regions 105a, 105c of the upper and lower devices 101, 140, and doesn't illustrate the drain regions 105b, 105d. The process 204 may include any appropriate techniques for forming the fins and source and drain regions, and dummy gate stack of a GAA device architecture having two vertically stacked GAA device, such as devices 101 and 140.

Note in this example of FIG. 3A, each of the source regions 105a and 105b includes a fully merged epitaxial structure, in that the epitaxial deposition grew from both the left and right nanoribbons to meet and merge to provide an overall diffusion region. In other embodiments, the epitaxial growth may be timed to not merge, such that there is a space between the two epitaxial growths, so the resulting structure would look similar to that shown in FIG. 3F1. That is, in such case, the two epitaxial regions would be unmerged, with the opening 305 of FIG. 3F1 between the two epitaxial regions. In such example cases, no recessing of the diffusion region (discussed with respect to FIGS. 3D-3F) would be needed, and processes 208, 212, and 216 of method 200 may be skipped.

As discussed herein previously, one of the devices 101 or 140 is a PMOS device, and the other of the devices 101 or 140 is an NMOS device. The doping profile and/or the material of the source and drain regions and/or the nanoribbons of a specific device may be in accordance with the type of the device. In an example, the device 101 is an NMOS device and the device 140 is a PMOS device, and the doping profile and/or the material of the source and drain regions and/or the nanoribbons of the devices 101 and 140 are selected accordingly, as also discussed herein previously. For example, source and drain regions of the device 140 can be PMOS source and drain regions that include, for example, group IV semiconductor materials such as silicon, germanium, SiGe, germanium tin (GeSn), SiGe alloyed with carbon (SiGe:C). Example p-type dopants include boron, gallium, indium, and aluminum. Source and drain regions of the device 101 can be NMOS source and drain regions that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. In one specific embodiment, PMOS source and drain regions are boron-doped SiGe, and NMOS source and drain regions are phosphorus-doped silicon. In a more general sense, the source and drain regions can be any semiconductor material suitable for a given application.

Referring again to FIG. 2A, the method 200 then proceeds from 204 to 205, where for each vertically stacked device 101, 140, the nanoribbons are released by removing the dummy gate to expose channel region and the sacrificial material are selectively removed from the exposed channel region, and the final gate stack is formed, as illustrated in FIG. 3B. The process 205 may include any appropriate techniques for releasing the nanoribbon, and forming the final gate stack of a GAA device architecture having two vertically stacked GAA device, such as devices 101 and 140. Thus, in the processes 204 and 205, a major portion of the vertically stacked devices 101 and 140, except, for example, the respective source and drain contacts and the layers 135, are formed. As illustrated in FIG. 3B, after process 205, the source and drain contacts of the devices have not yet formed, the source and drain regions of individual devices are covered by respective dielectric material 315. For example, dielectric material 315 is above the source region 105a of the upper device, and covers the source region 105a.

Referring again to FIG. 2A, the method 200 then proceeds from 205 to 206, where for the upper device 101, the source trench is opened (e.g., by removing dielectric material 315 from above the source region 105a), to expose the underlying source region 105a, as illustrated in FIG. 3C. As a result, an opening 305 is formed above the source region 105a. In an example, at process 206, the source trench (and also the drain trench) is opened for the upper device 101, and not for the lower device 140, as illustrated in FIG. 3C.

Referring again to FIG. 2A, the method 200 then proceeds from 206 to 208, where a layer of liner 102 is deposited on walls of gate spacers 132, on the dielectric material 117 above the gate electrodes 125, and above the source region 105a, and a protective layer 304 is deposited on top surfaces of the liner 102, as illustrated in FIG. 3D. The protective layer 304 allows the lower lateral portion of liner 102 to be selectively removed from above the source region 105a, as illustrated in FIG. 3E. For example, the liner 102 may initially be deposited on walls of the gate spacers 132 and also above the source region 105a, as illustrated in FIG. 3D. Subsequently, protective layer 304 is selectively deposited on the upper layer of liner 102 and less so on the lower surface of 102 given, for example, a directional nature of the deposition and/or aspect ratio of trench 305 (e.g., trench 305 is five or more time taller than it is wide, and is even narrower once liner 102 is deposited), according to an embodiment. With the protective layer 304 in place, the horizontal section of the liner 102 may be etched and removed from above the source region 105a, such that the liner remains on walls of gate spacers 132 and only partially above the source region 105a, thereby once again extending opening 305 down to a surface of the source region 105a, as illustrated in FIG. 3E. A directional etch that is selective to the material of protective layer 304 can be used to remove that portion of liner 102. Note that, in some cases, protective layer 304 may also deposit on top of that portion of liner 102, but that lower layer 304 is thinner than the upper layer 304 (e.g., because is it more difficult to deposit layer 304 into the trench 305 that is now even narrower due to presence of liner 102, particularly when a directional deposition is used to provide protective layer 304), and that thinner portion of the layer 304 can thus be completely removed along with liner 102 by the directional etch, while at least some of the thicker upper portion of layer 304 survives the selective etch.

As illustrated in FIG. 3E, the liner 102 defines the recess or opening 305 above a top surface of the source region 105a. In an example, the liner 102 may also be deposited above the gate stack, including the dielectric material 117 above the gate electrode 125. The liner 102 and protective layer 304 may each be deposited using an appropriate deposition technique, such as chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. As explained above, a directional deposition may be used for the protective layer 304, to facilitate its selective or otherwise more substantial deposition on the upper surface of the structure, relative to the lower surface within trench 305. In an example, a thickness or width of the liner 102 (as may be trimmed by the directional etch described above) dictates a width of the opening 305, which in turn dictates the width of the source contact 118a to be eventually formed within the source region 105a.

In an example, the liner 102 and protective layer 304 are both etch selective with respect to the material of the source regions 105a, 105b. For example, an etch process that etches the source regions may not substantially etch (or etch at a substantially slower rate) the liner 102 or layer 304. As will be seen herein later in turn, the liner 102 protects the gate spacers 132 and the gate electrode 125 (and the dielectric material 117), when a recess for a source contact is formed within the source regions 105a, 105b. An example of the liner 102 may comprises silicon nitride, or another appropriate nitride, oxide, carbide, oxycarbide, oxynitride, or oxycarbonitride.

Also, note that in this example the protective layer 304 acts as a “helmet” in the sense that it protects the liner 102, e.g., when the recess within the source region 105a is formed (discussed herein later). Similar to the liner 102, the protective layer 304 also is etch selective to the material of the source region 105a. In an example, the protective layer 304 comprises an appropriate nitride, oxide, carbide, oxycarbide, oxynitride, or oxycarbonitride, for example, titanium nitride (TiN). In another example, layer 304 may be removed before performing the selective etch of source region 105a, such that only liner 102 remains during that selective etch.

Referring again to FIG. 2A, the method 200 then proceeds from 208 to 212, where portions of the source regions 105a and 105c of the upper and lower devices 101, 140 and the isolation region 150 between the two source regions are removed, so as to extend the opening 305 within the source regions 105a, 105b of the upper and lower devices, as illustrated in FIG. 3F. An anisotropic and/or directional etch can be performed, to extend the opening 305 within a central section of the source regions, with the liner 102 protecting the peripheral sections of the source regions. The etch process is selective to the liner 102 and the protective layer 304, such that a rate of etching the source regions 105a, 105c is substantially faster than a rate of etching the liner 102 and/or the protective layer 304. Accordingly, after the etch process 212, the liner 102 and the protective layer 304 continue to cover the walls of the gate spacer 132 and the gate electrode 125. As illustrated, the etch process extends through the isolation structure 150. The substrate 144, including the conductive structure 157a, may act as an etch stop layer. For example, the opening 305 extends up to the substrate and the conductive structure 157a. In an example, the opening 305 may be slightly tapered (e.g., a lower section of the opening 305 near the substrate 144 has a lower diameter than an upper section of the opening 305). This may be a consequence of etching a deep opening 305 within the source regions 105a. 105b. However, in another example, the opening 305 may be substantially non-tapered.

Referring again to FIG. 2A, the method 200 then proceeds from 212 to 216, where the protective layer 304 and at least a part of the liner 102 are removed, as illustrated in FIG. 3F1. For example, an isotropic etch process may be employed that is selective to the material of the source regions 105a, 105b (e.g., does not substantially etch, or etch at a much slower rate, the source regions). In an example, an entirety of the liner 102 may be removed. In another example, some sections of the liner 102 may remain, such as the vertical sections of the liner 102 on the sidewalls of the gate spacers 132, as illustrated in FIG. 3F1.

Referring again to FIG. 2A, the method 200 then proceeds from 216 to 220, where first one or more metals 328 are deposited on sidewalls of the opening 305, as illustrated in FIG. 3G. In an example, the deposited first one or more metals 328 have (i) an upper portion extending through the source region 105a of the upper device 101, (ii) a middle portion extending through the isolation region 150, and (iii) a lower portion extending within the source region 105c of the lower device 101. In an example, the first one or more metals 328 are suitable for forming the layers 135c and 135d of the lower device 140. Merely as an example, the lower device 140 may be a PMOS device, and in such an example, the first one or more metals 328 are suitable for forming the layers 135 of the PMOS device. Examples of such metals include one or more nickel, platinum, molybdenum, niobium, cobalt, tungsten, rhenium, rhodium, and iridium, as discussed herein previously. The first one or more metals 328 may be deposited using an appropriate deposition technique, such as CVD, PVD, ALD, VPE, MBE, or LPE, for example.

The example of FIG. 3G illustrates the first one or more metals 328 being deposited on entire sidewalls of the opening 305. However, in another example, the deposition process can be controlled, such that the first one or more metals 328 are deposited on semiconductor materials (such as on sidewalls of the semiconductor materials of the source regions 105a and 105c) and not on the non-conductive or dielectric material of the isolation region 150 or the liner 102, e.g., as illustrated in FIG. 3G1.

Referring again to FIG. 2A, the method 200 then proceeds from 220 to 224, where a hard mask 330 is deposited within a bottom section of the opening 305, as illustrated in FIG. 3H. In an example, the hard mask 330 covers the lower portion of the first one or more metals 328 (where the lower portion extends within the source region 105c) and at least a part of the middle portion of the first one or more metals 328 (where the middle portion extends through the isolation region 150), as illustrated in FIG. 3H. The hard mask 330 may be deposited using an appropriate deposition technique, such as CVD, PVD, ALD, VPE, MBE, or LPE, for example. In an example, the hard mask 330 is selective to the material of the source regions 105a, 105c and the first one or more metals 328. For example, an etch process to remove the first one or more metals 328 may not substantially etch (or etch at a substantially slower rate) the hard mask 330. Similarly, an etch process to remove the hard mask 330 may not substantially etch (or etch at a substantially slower rate) the source regions 105a, 105c. An example of the hard mask may be a carbon hard mask (CHM) and/or may include an appropriate nitride, oxide, carbide, oxycarbide, oxynitride, or oxycarbonitride.

The method 200 of FIG. 2A then proceeds from 224 to 228 of FIG. 2B, where the upper portion and at least another part of the middle portion of the first one or more metals 328, which are not covered by the hard mask 330, are removed, as illustrated in FIG. 3I. Thus, the first one or metals 328 are recessed from the top. For example, the lower portion and at least the part of the middle portion of the first one or more metals 328, which are protected by the hard mask 330, remain. An appropriate selective etch process may be used, where the etch process removes the upper portion of the first one or more metals 328, without substantially etching (or etching at a substantially slower rate) the hard mask 330.

Referring again to FIG. 2B, the method 200 then proceeds from 228 to 232, where the hard mask 330 is removed, as illustrated in FIG. 3J. In some embodiments where the hard mask 330 is a carbon hard mask (CHM), the removal at 232 can be accomplished with an ashing process. In a more general sense, the removal at 232 can be accomplished with a selective etch process, such that the hard mask 330 etches much faster than the source regions 105a, 105c and the first one or more metals 328.

Referring again to FIG. 2B, the method 200 then proceeds from 232 to 236, where second one or more metals 329 are deposited on sidewalls of the opening 305, as illustrated in FIG. 3K. In an example, the deposited second one or more metals 329 have (i) an upper portion extending through the source region 105a and on sidewalls of the source region 105a, (ii) a lower portion on the first one or more metals 328, as illustrated. In an example, the second one or more metals 329 are suitable for forming the layers 135a and 135b of the upper device 101. Merely as an example, the upper device 101 may be an NMOS device, and in such an example, the second one or more metals 329 are suitable for forming the layers 135 of the NMOS device. Examples of such metals include one or more of titanium, aluminum, gadolinium, erbium, and scandium. Thus, the second one or more metals 329 are different from the first one or more metals 328 (e.g., have different work functions matched with the respective devices, as discussed herein previously). The second one or more metals 329 may be deposited using an appropriate deposition technique, such as CVD, PVD, ALD, VPE, MBE, or LPE, for example.

Referring again to FIG. 2B, the method 200 then proceeds from 236 to 240, where the first one or more metals 328 and the second one or more metals 329 are processed (e.g., where the processing includes annealing at a high temperature), to respectively form the layers 135c and 135a. Any unreacted remnants of the first and second metals may be removed or etched, after formation of the layers 135. The layers 135a, 135c, after removal of the unreacted remnants of the first and second metals, are illustrated in FIG. 3L.

For example, in FIG. 3K, as the first one or more metals 328 are adjacent to the sidewalls of the source region 105c of the lower device 140, the first one or more metals 328 react with the semiconductor material (e.g., Si and/or Ge) of the source region 105c of the lower device 140, to form the layer 135c comprising silicide, germanide, and/or germanosilicide. Note that the lower portion of the second one or more metals 329, which are on the inner walls of the first one or more metals 328 (see FIG. 3K), are not adjacent to the source region 105c of the lower device 140. Accordingly, the lower portion of the second one or more metals 329, which are on the inner walls of the first one or more metals 328, cannot react with the source region 105c of the lower device 140. Thus, the lower portion of the second one or more metals 329, which are on the inner walls of the first one or more metals 328, remain unreacted, and are removed after formation of the layers 135. In an example, the lower device 140 is a PMOS device in which the source and drain regions comprise SiGe, and the corresponding layer 135c may comprise silicide, germanide, and/or germanosilicide of the first one or more metals (and not of the second one or more metals 329).

Similarly, as the second one or more metals 329 are adjacent to the sidewalls of the source region 105a of the upper device 101, the second one or more metals 329 react with the semiconductor material (e.g., Si and/or Ge) of the source region 105a of the upper device 101, to form the layer 135a comprising silicide, germanide, and/or germanosilicide. Note that the first one or more metals 328 are not adjacent to the source region 105a of the upper device 101. Accordingly, the silicide, germanide, and/or germanosilicide of the layer 135a of the upper device 101 are of the second one or more metals 329 (and not of the first one or more metals 328). In an example, the upper device 101 is an NMOS device in which the source and drain regions comprise silicon, the corresponding layer 135a may comprise silicide of the second one or more metals 329.

Referring again to FIG. 2B, the method 200 then proceeds from 240 to 244. In process 244, conductive material may be deposited within the opening 305 extending within the source regions 105a and 105c, to respectively form the source contacts 118a and 118c, as illustrated in FIG. 3M. Note that the source contacts 118a, 118c, in combination, form a continuous and monolithic contact, which also extends through the isolation region 150. In an example, top portion of the deposited conductive materials may be planarized using an appropriate planarization technique, such as mechanical polishing or chemical-mechanical polishing (CMP). This completes formation of the source contacts 118a, 118c of the devices 101, 140, respectively.

Note that unlike the source contacts 118a, 118c that are continuous, the drain contacts 118b, 118d may be discontinuous (e.g., see FIG. 1A), for example. The process 244 may be appropriately modified for the drain contacts 118b, 118d. For example, the lower drain contact 118d may be deposited from the frontside, followed by deposition of dielectric material of the isolation region 150, and the conductive material of the upper drain contact 135b may be deposited, to form the discontinuous drain contacts 118b, 118d of FIG. 1A. In another example, the upper drain contact 118b may be deposited from the frontside, and the lower drain contact 118d may be deposited from the backside. In the example where the lower drain contact 118d is deposited from the backside, the silicidation process for formation of the layer 135d adjacent to the lower drain region 105d may also be performed from the backside. In such as example, the isolation structure 150 would prevent the backside silicidation process for formation of the layer 135d and/or the backside contact 118d deposition process to impact the drain region 105b and/or the layer 135b of the upper device 101.

Referring again to FIG. 2B, the method 200 then proceeds from 244 to 248. At 248, a general integrated circuit (IC) is completed, as desired, in accordance with some embodiments. Such additional processing to complete an IC may include forming conductive vias 119 through the dielectric material 117 above the gate contact 129b (see FIG. 3N), to couple the gate contact 129b with interconnect features on the frontside of the die, back-end or back-end-of-line (BEOL) processing to form one or more metallization layers and/or to interconnect the transistor devices formed, for example. Any other suitable processing may be performed, as will be apparent in light of this disclosure.

Note that the processes in method 200 are shown in a particular order for ease of description. However, one or more of the processes may be performed in a different order or may not be performed at all (and thus be optional), in accordance with some embodiments. Numerous variations on method 200 and the techniques described herein will be apparent in light of this disclosure.

### Example System

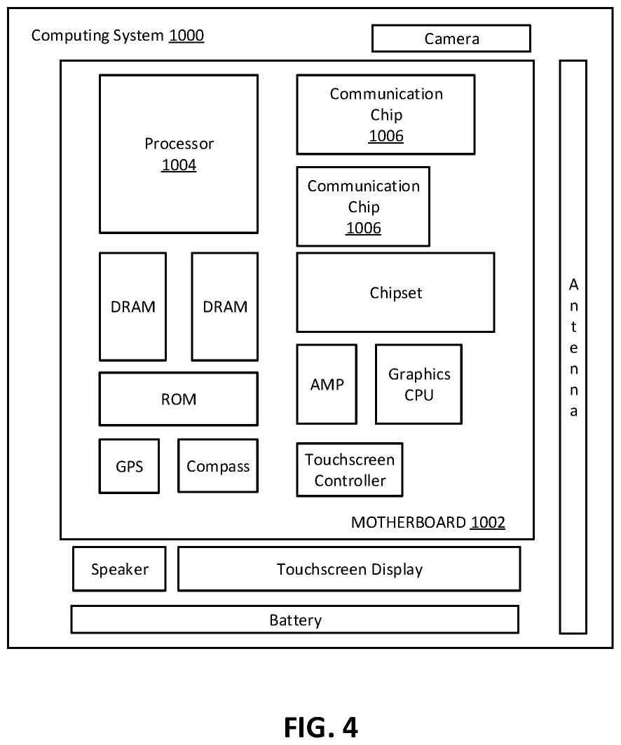

FIG. 4 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit structure, comprising: a first device comprising (i) a first source or drain region, (ii) a first source or drain contact coupled to the first source or drain region, and (iii) a first layer comprising a first metal and first one or more semiconductor materials between at least a section of the first source or drain region and the first source or drain contact; and a second device stacked vertically above the first device, the second device comprising (i) a second source or drain region, (ii) a second source or drain contact coupled to the second source or drain region, and (iii) a second layer comprising a second metal and second one or more semiconductor materials between at least a section of the second source or drain region and the second source or drain contact, wherein the first metal and the second metal are elementally different.

Example 2. The integrated circuit of example 1, wherein the second source or drain region is above the first source or drain region, and wherein the integrated circuit further comprises an isolation region comprising non-conductive material between the second source or drain region and the first source or drain region.

Example 3. The integrated circuit of example 2, wherein the first source or drain contact and the second source or drain contact form a continuous contact extending through the isolation region.

Example 4. The integrated circuit of any one of examples 1-3, wherein the first one or more semiconductor materials comprise one or both of silicon and germanium, and wherein the second one or more semiconductor materials comprise one or both of silicon and germanium.

Example 5. The integrated circuit of any one of examples 1-4, wherein the first layer comprises silicide, germanide, and/or germanosilicide of the first metal, and wherein the second layer comprises silicide, germanide, and/or germanosilicide of the second metal.

Example 6. The integrated circuit of any one of examples 1-5, wherein the first metal comprises one of nickel, platinum, molybdenum, niobium, cobalt, tungsten, rhenium, rhodium, or iridium.

Example 7. The integrated circuit of example 6, wherein the first device is a p-channel metal-oxide semiconductor (PMOS) device.

Example 8. The integrated circuit of any one of examples 1-7, wherein the second metal comprises one of titanium, aluminum, gadolinium, erbium, or scandium.

Example 9. The integrated circuit of example 8, wherein the second device is a n-channel metal-oxide semiconductor (NMOS) device.

Example 10. The integrated circuit of any one of examples 1-9, wherein: the first device is a p-channel metal-oxide semiconductor (PMOS) device; the first metal comprises one of nickel, platinum, molybdenum, niobium, cobalt, tungsten, rhenium, rhodium, or iridium; the second device is a n-channel metal-oxide semiconductor (NMOS) device; and the second metal comprises one of titanium, aluminum, gadolinium, erbium, or scandium.

Example 11. The integrated circuit of any one of examples 1-10, wherein the first device and the second device are coupled in a complementary metal oxide semiconductor (CMOS) architecture.

Example 12. The integrated circuit of any one of examples 1-11, wherein the work function of the first metal is different from the work function of the second metal.

Example 13. The integrated circuit of any one of examples 1-12, wherein the work function of the first metal is greater than the work function of the second metal.

Example 14. The integrated circuit of any one of examples 1-13, wherein the first source or drain contact is above and at least in part aligned with the second source or drain contact, such that an imaginary vertical line passes through both the first source or drain contact and the second source or drain contact.

Example 15. The integrated circuit of any one of examples 1-14, wherein: the first device further comprises (i) a third source or drain region, (ii) a first plurality of bodies comprising semiconductor material laterally extending from the first source or drain region to the third source or drain region, and (iii) a first gate stack at least in part wrapped around one or more of the first plurality of bodies; and the second device further comprises (i) a fourth source or drain region, (ii) a second plurality of bodies comprising semiconductor material laterally extending from the second source or drain region to the fourth source or drain region, and (iii) a second gate stack at least in part wrapped around one or more of the second plurality of bodies.

Example 16. The integrated circuit of example 15, wherein the first plurality of bodies comprises a vertical stack of a plurality of nanoribbons, nanowires, or nanosheets.

Example 17. An integrated circuit structure, comprising: a lower device comprising (i) a first source region, (ii) a first source contact extending within the first source region, and (iii) a first silicide and/or germanide layer comprising a first metal, the first silicide and/or germanide layer between at least a section of the first source region and the first source contact; an upper device stacked vertically above the lower device, the upper device comprising (i) a second source region above the first source region, (ii) a second source contact extending within the second source region, and (iii) a second silicide and/or germanide layer comprising a second metal, the second silicide and/or germanide layer between at least a section of the second source region and the second source contact, wherein a work function of the first metal is different from a work function of the second metal; and an isolation structure between the first source region and the second source region.

Example 18. The integrated circuit of example 17, wherein the second source contact is above and at least in part aligned with the first source contact, such that an imaginary vertical line passes through both the first and second source contacts.

Example 19. The integrated circuit of any one of examples 17-18, wherein: the lower device further comprises (i) a first drain region, (ii) a first drain contact extending within the first drain region, and (iii) a third silicide and/or germanide layer comprising the first metal, the third silicide and/or germanide layer between at least a section of the first drain region and the first drain contact; and the upper device further comprises (i) a second drain region above the first drain region, (ii) a second drain contact extending within the second drain region, and (iii) a fourth silicide and/or germanide layer comprising the second metal, the fourth silicide and/or germanide layer between at least a section of the second drain region and the second drain contact.

Example 20. The integrated circuit of example 19, wherein the second drain contact is above and at least in part aligned with the first drain contact, such that an imaginary vertical line passes through both the first and second drain contacts.

Example 21. The integrated circuit of any one of examples 17-20, wherein: the lower device comprises a first plurality of bodies laterally extending from the first source region to the first drain region; and the upper device comprises a second plurality of bodies laterally extending from the second source region to the second drain region.

Example 22. The integrated circuit of example 21, wherein each of the first and second plurality of bodies comprise a corresponding vertical stack of nanoribbons or nanowires.

Example 23. The integrated circuit of any one of examples 17-22, wherein the upper device is an n-type MOS (NMOS) device, and the lower device is a p-type MOS (PMOS) device.

Example 24. The integrated circuit of any one of examples 17-23, wherein the first source region comprises silicon and germanium doped with p type dopants, and the second source region comprises silicon doped with n type dopants.

Example 25. An integrated circuit comprising: an upper transistor device vertically stacked above a lower transistor device, wherein the upper transistor device comprises first one or more silicide and/or germanide layers in contact with an upper source region and/or an upper drain region of the upper device, wherein the lower transistor device comprises second one or more silicide and/or germanide layers in contact with a lower source region and/or a lower drain region of the lower device, and wherein the first one or more silicide and/or germanide layers comprise a first metal that is elementally different from a second metal of the second one or more silicide and/or germanide layers.

Example 26. The integrated circuit of example 25, wherein the first one or more silicide and/or germanide layers comprise the first metal and one or both of silicon and germanium, and wherein the second one or more silicide and/or germanide layers comprise the second metal and one or both of silicon and germanium.

Example 27. The integrated circuit of any one of examples 25-26, wherein: the upper device is an n-type MOS (NMOS) device, and the first one or more silicide and/or germanide layers comprises a first silicide layer comprising the first metal and silicon; and the lower device is a p-type MOS (PMOS) device, and the second one or more silicide and/or germanide layers comprises (i) a second silicide layer comprising the second metal and silicon, and (ii) a germanide layer comprising the second metal and germanium.

Example 28. The integrated circuit of any one of examples 25-27, wherein: the first metal one of titanium, aluminum, gadolinium, erbium, or scandium; and the second metal comprises one of nickel, platinum, molybdenum, niobium, cobalt, tungsten, rhenium, rhodium, or iridium.

Example 29. The integrated circuit of any one of examples 25-28, wherein each of the upper and lower transistor devices is a nanoribbon or nanowire transistor device.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit structure, comprising:
a first device comprising (i) a first source or drain region, (ii) a first source or drain contact coupled to the first source or drain region, and (iii) a first layer comprising a first metal and first one or more semiconductor materials between at least a section of the first source or drain region and the first source or drain contact; and
a second device stacked vertically above the first device, the second device comprising (i) a second source or drain region, (ii) a second source or drain contact coupled to the second source or drain region, and (iii) a second layer comprising a second metal and second one or more semiconductor materials between at least a section of the second source or drain region and the second source or drain contact, wherein the first metal and the second metal are elementally different.

2. The integrated circuit of claim 1, wherein the second source or drain region is above the first source or drain region, and wherein the integrated circuit further comprises an isolation region comprising non-conductive material between the second source or drain region and the first source or drain region.

3. The integrated circuit of claim 2, wherein the first source or drain contact and the second source or drain contact form a continuous contact extending through the isolation region.

4. The integrated circuit of claim 1, wherein the first one or more semiconductor materials comprise one or both of silicon and germanium, and wherein the second one or more semiconductor materials comprise one or both of silicon and germanium.

5. The integrated circuit of claim 1, wherein the first layer comprises silicide, germanide, and/or germanosilicide of the first metal, and wherein the second layer comprises silicide, germanide, and/or germanosilicide of the second metal.

6. The integrated circuit of claim 1, wherein the first metal comprises one of nickel, platinum, molybdenum, niobium, cobalt, tungsten, rhenium, rhodium, or iridium.

7. The integrated circuit of claim 6, wherein the first device is a p-channel metal-oxide semiconductor (PMOS) device.

8. The integrated circuit of claim 1, wherein the second metal comprises one of titanium, aluminum, gadolinium, erbium, or scandium.

9. The integrated circuit of claim 8, wherein the second device is a n-channel metal-oxide semiconductor (NMOS) device.

10. The integrated circuit of claim 1, wherein:
the first device is a p-channel metal-oxide semiconductor (PMOS) device;
the first metal comprises one of nickel, platinum, molybdenum, niobium, cobalt, tungsten, rhenium, rhodium, or iridium;
the second device is a n-channel metal-oxide semiconductor (NMOS) device; and
the second metal comprises one of titanium, aluminum, gadolinium, erbium, or scandium.

11. The integrated circuit of claim 1, wherein the first device and the second device are coupled in a complementary metal oxide semiconductor (CMOS) architecture.

12. The integrated circuit of claim 1, wherein the work function of the first metal is greater than the work function of the second metal.

13. The integrated circuit of claim 1, wherein the first source or drain contact is above and at least in part aligned with the second source or drain contact, such that an imaginary vertical line passes through both the first source or drain contact and the second source or drain contact.

14. The integrated circuit of claim 1, wherein:
the first device further comprises (i) a third source or drain region, (ii) a first plurality of bodies comprising semiconductor material laterally extending from the first source or drain region to the third source or drain region, and (iii) a first gate stack at least in part wrapped around one or more of the first plurality of bodies; and
the second device further comprises (i) a fourth source or drain region, (ii) a second plurality of bodies comprising semiconductor material laterally extending from the second source or drain region to the fourth source or drain region, and (iii) a second gate stack at least in part wrapped around one or more of the second plurality of bodies.

15. The integrated circuit of claim 14, wherein the first plurality of bodies comprises a vertical stack of a plurality of nanoribbons, nanowires, or nanosheets.

16. An integrated circuit structure, comprising:
a lower device comprising (i) a first source region, (ii) a first source contact extending within the first source region, and (iii) a first silicide and/or germanide layer comprising a first metal, the first silicide and/or germanide layer between at least a section of the first source region and the first source contact;
an upper device stacked vertically above the lower device, the upper device comprising (i) a second source region above the first source region, (ii) a second source contact extending within the second source region, and (iii) a second silicide and/or germanide layer comprising a second metal, the second silicide and/or germanide layer between at least a section of the second source region and the second source contact, wherein a work function of the first metal is different from a work function of the second metal; and
an isolation structure between the first source region and the second source region.

17. The integrated circuit of claim 16, wherein:
the lower device further comprises (i) a first drain region, (ii) a first drain contact extending within the first drain region, and (iii) a third silicide and/or germanide layer comprising the first metal, the third silicide and/or germanide layer between at least a section of the first drain region and the first drain contact; and
the upper device further comprises (i) a second drain region above the first drain region, (ii) a second drain contact extending within the second drain region, and (iii) a fourth silicide and/or germanide layer comprising the second metal, the fourth silicide and/or germanide layer between at least a section of the second drain region and the second drain contact.

18. The integrated circuit of claim 16, wherein the first source region comprises silicon and germanium doped with p type dopants, and the second source region comprises silicon doped with n type dopants.

19. An integrated circuit comprising:
an upper transistor device vertically stacked above a lower transistor device,
wherein the upper transistor device comprises first one or more silicide and/or germanide layers in contact with an upper source region and/or an upper drain region of the upper device,
wherein the lower transistor device comprises second one or more silicide and/or germanide layers in contact with a lower source region and/or a lower drain region of the lower device, and
wherein the first one or more silicide and/or germanide layers comprise a first metal that is elementally different from a second metal of the second one or more silicide and/or germanide layers.

20. The integrated circuit of claim 19, wherein:
the upper device is an n-type MOS (NMOS) device, and the first one or more silicide and/or germanide layers comprises a first silicide layer comprising the first metal and silicon; and
the lower device is a p-type MOS (PMOS) device, and the second one or more silicide and/or germanide layers comprises (i) a second silicide layer comprising the second metal and silicon, and (ii) a germanide layer comprising the second metal and germanium.

21. The integrated circuit of claim 19, wherein:
the first metal one of titanium, aluminum, gadolinium, erbium, or scandium; and
the second metal comprises one of nickel, platinum, molybdenum, niobium, cobalt, tungsten, rhenium, rhodium, or iridium.
